(19) United States
(12) Patent Application Publication
(10) Pub. No.: US 2013/0049591 A1
(43) Pub. Date: Feb. 28, 2013

(54) FLUORESCENT LAMP SUPPORT

(71) Applicant: Leviton Manufacturing Company, Inc., Melville, NY (US)

(72) Inventors: Robert Quercia, Garden City, NY (US); Gregory Galluccio, Hauppauge, NY (US); Anthony Tufano, N. Massapequa, NY (US); Francisco Schapira, Valley Stream, NY (US); Ruel Sarino, Port Washington, NY (US); Robert Hick, Newburg, OR (US); Thomas Leonard, Tualatin, OR (US)

(73) Assignee: Leviton Manufacturing Company, Inc., Melville, NY (US)

(21) Appl. No.: 13/662,670

(22) Filed: Oct. 29, 2012

Related U.S. Application Data
(63) Continuation-in-part of application No. 12/770,468, filed on Apr. 29, 2010.
Application No. 12/770,468 is a continuation-in-part of application No. 12/679,980, filed on Mar. 24, 2011.
Application No. 12/679,980 is a continuation-in-part of application No. 12/173,171, filed on Jul. 15, 2008, now Pat. No. 8,113,684.
(60) Provisional application No. 61/144,612, filed on Jan. 14, 2009.

(51) Int. Cl. H05B 37/02; H05K 13/00; H05B 37/04

(52) U.S. Cl. 315/86; 315/155; 315/307; 29/592.1

(57) ABSTRACT

Modular light fixtures and methods for constructing modular light fixtures are provided. A modular light fixture in one embodiment comprises a first end section having a first housing and a first lamp holder, a second end section having a second lamp holder, and a ballast located in an interior of the first housing. The modular light fixture also includes at least one environmental sensor configured to sense at least one environmental condition and an electronic control circuit configured to receive a signal indicative of the at least one environmental condition sensed by the at least one environmental sensor. The first lamp holder is configured to support a first end of a lamp and the second lamp holder is configured to support a second end of the lamp.

### CROSS-REFERENCE TO RELATED APPLICATIONS

This application is a continuation-in-part of co-pending U.S. application Ser. No. 12/770,468, filed on Apr. 29, 2010, which is a continuation-in-part of co-pending U.S. application Ser. No. 12/679,980, which is a 35 U.S.C. § 371 filing of International Application No. PCT/US09/50742, filed Jul. 15, 2009, which claims the benefit of U.S. Provisional Application No. 61/144,612, filed on Jan. 14, 2009, and is a continuation-in-part of U.S. Nonprovisional application Ser. No. 12/173,171, filed on Jul. 15, 2008, now U.S. Pat. No. 8,113,684, all of which are hereby incorporated by reference herein in their entireties.

### FIELD OF TECHNOLOGY

This application relates to apparatus and methods for supporting and powering fluorescent lamps. In particular, the application relates to apparatus and methods for distributing power from a ballast to a lamp holder.

### BACKGROUND OF THE INVENTION

Fluorescent lamp holders are typically installed in a sheet metal fixture with a ballast and associated wiring. The manufacturer will generally assemble the lamp holders to the sheet metal fixture, attach the ballast to the fixture, and run wires between the ballast and lamp holders. This process can be labor intensive and may lead to wiring errors and an unappealing installation.

FIG. 1 shows typical light fixture 100. Light fixture 100 may include enclosure 102. Enclosure 102 may be a fixture housing. Surface 103 of enclosure 102 may be a reflector. Surface 103 may have breaks in slope 105 to direct light in selected directions. Light fixture 100 may include lamp holders 104, 106 and 108. Lamp holders 104, 106 and 108 may each hold one end of a tube-type fluorescent lamp. The other end of each lamp may be held by lamp holders 110, 112 and 114, respectively. Arrows A, B and C show where fluorescent tubes would be placed between corresponding lamp holders. The lamp holders are fixed directly to enclosure 102.

FIG. 2 shows typical lamp holder 200. Lamp holder 200 may includes base 202, body 204, lamp pin guide 206 and pin slot 208. Paired contact pins from a fluorescent lamp may be inserted into slot 208 until the pins occupy positions 210 and 212. The pins may then be rotated in direction A about rotational axis X until the pins contact power terminals 214 and 216 (shown in broken line) inside body 204 of lamp holder 200.

Long wiring leads that may be required to provide power to typical lamp holder 200 in typical light fixture 100 may promote errors during assembly, transport or installation and may make lamp fixture assembly expensive with respect to both labor and materials. In addition, lamp holder 200 is typically mechanically secured to enclosure 102, making future adjustments of its position impossible.

It would be desirable, therefore, to provide apparatus and methods that improve the process of assembling lamp fixture components.

It would be further desirable, therefore, to provide apparatus and methods that reduce the likelihood of manufacturing errors.

### SUMMARY OF THE INVENTION

The present disclosure describes various implementations of modular light fixtures. In one embodiment, a modular light fixture comprises a first end section having a first housing and a first lamp holder, a second end section having a second lamp holder, a ballast located in an interior of the first housing, at least one environmental sensor configured to sense at least one environmental condition, and an electronic control circuit configured to receive a signal indicative of the at least one environmental condition sensed by the at least one environmental sensor. The first lamp holder is configured to support a first end of a lamp and the second lamp holder is configured to support a second end of the lamp.

The modular light fixture may also comprise at least one control conductor configured to communicate signals between the first end section and the second end section. The second end section comprises a second housing, wherein the electronic control circuit is located in an interior of the second housing, and wherein the electronic control circuit is configured to communicate control signals to the ballast via the at least one control conductor.

In some embodiments, the at least one environmental sensor comprises at least one occupancy sensor configured to detect whether or not a space, which is at least partially illuminated by the lamp, is occupied by at least one person. For example, when the space is not occupied for a predetermined length of time, the electronic control circuit is configured to send a control signal along the at least one control conductor to instruct the ballast to turn the lamp off. Alternatively, when the space is not occupied for a predetermined length of time, the electronic control circuit is configured to send a control signal along the at least one control conductor to instruct the ballast to dim the lamp.

The at least one environmental sensor may comprise at least one photosensor configured to detect an amount of light in a space that is at least partially illuminated by the lamp. The electronic control circuit may be configured to determine a portion of the detected amount of light that is independent of the effect of the illumination of the lamp. When the portion of the detected amount of light is above a predetermined level, the electronic control circuit may be configured to send a control signal along the at least one control conductor to cause the ballast to turn the lamp off. Alternatively, when the portion of the detected amount of light is above a predetermined level, the electronic control circuit may be configured to send a control signal along the at least one control conductor to cause the ballast to dim the lamp.

Furthermore, the first end section may comprise a third lamp holder and the second end section may comprise a fourth lamp holder, wherein the third lamp holder is configured to support a first end of a second lamp and the fourth lamp holder is configured to support a second end of the second lamp. The first end section may comprise at least one fifth lamp holder and the second end section may comprise at least one sixth lamp holder, wherein the at least one fifth lamp holder is configured to support a first end of at least one third lamp and the at least one sixth lamp holder is configured to support a second end of the at least one third lamp.

The modular light fixture may further comprise a wireless receiver coupled to the electronic control circuit. The wireless receiver is configured to receive wireless signals that include information regarding the illumination of the lamp and the electronic control circuit may be configured to individually illuminate the lamp according to the received wireless signals. The wireless receiver may be configured to receive automated demand response (ADR) signals from a power utility company, wherein the electronic control circuit is configured to control the lamp according to the ADR signals. The modular light fixture may further comprise an addressing switch associated with the electronic control circuit, wherein the addressing switch is configured to provide a first address to the controller circuit for identifying the lamp. For example, the addressing switch may be programmable and/or may be a hardware switch.

In some embodiments, the modular light fixture may further comprise a reflector. The first end section may further comprise a first clip and a second clip and the second end section further comprises a third clip and a fourth clip. The first clip, second clip, third clip, and fourth clip may be configured to be removably attached to the reflector for supporting the reflector. The modular light fixture may further comprise an enclosure configured to support the first end section, second end section, and reflector to form a unitary structure.

The modular light fixture may further comprise at least one power conductor configured to provide power to the ballast and the electronic control circuit. Also, the ballast may comprise a dimming ballast, which, for example, may provide stepwise dimming.

The modular light fixture may further comprise an emergency backup power supply contained within one of the first housing or the second housing. The emergency backup power supply may comprise at least one rechargeable battery, a charging circuit configured to charge the at least one rechargeable battery, and a power outage detecting circuit configured to detect the occurrence of a power outage. When the power outage detecting circuit detects a power outage, the at least one rechargeable battery may be configured to provide power to the ballast and electronic control circuit. The charging circuit may be configured to charge the at least one rechargeable battery from power that is also supplied to the ballast and electronic control circuit. Alternatively, the charging circuit may be configured to charge the at least one rechargeable battery from power supplied by a remote circuit.

According to various implementations, the lamp may be a fluorescent lamp. Alternatively, the lamp may be a light emitting diode (LED) lamp.

The present disclosure describes implementations of other modular light fixtures, such as a modular light fixture comprising a first end section having a first end section having a first housing and a first lamp holder and a second end section having a second housing and a second lamp holder, the first lamp holder being configured to support a first end of a lamp and the second lamp holder being configured to support a second end of the lamp. The first end section being electrically coupled to the second end section. A ballast may be located in an interior of the first housing and an emergency backup power supply may be contained within one of the first housing or the second housing.

The modular light fixture may further comprise at least one environmental sensor configured to sense at least one environmental condition and an electronic control circuit configured to receive signals indicative of the at least one environmental condition. The second end section may comprise a second housing, wherein the electronic control circuit is located in an interior of the second housing. The electronic control circuit may be configured to communicate control signals to the ballast via the at least one control conductor. The at least one environmental sensor may comprise at least one occupancy sensor configured to detect whether or not a space, which is at least partially illuminated by the lamp, is occupied by at least one person.

The at least one environmental sensor may comprise at least one photosensor configured to detect an amount of light in a space that is at least partially illuminated by the lamp. The electronic control circuit is configured to determine a portion of the detected amount of light that is independent of the effect of the illumination of the lamp. The modular light fixture may further comprise at least one power conductor configured to provide power to the ballast and the electronic control circuit.

The present disclosure also describes, among other things, a modular light fixture comprising a first end section having a first housing, a first lamp holder, a first clip, and a second clip, a second end section having a second lamp holder, a third clip, and a fourth clip, a ballast located in an interior of the first housing, and a reflector attached to the first clip, second clip, third clip, and fourth clip. The first lamp holder is configured to support a first end of a lamp and the second lamp holder is configured to support a second end of the lamp.

In some embodiments of the modular light fixture, the reflector is removably attached to the first clip, second clip, third clip, and fourth clip. The modular light fixture may further comprise an enclosure configured to support the first end section, second end section, and reflector to form a unitary structure. The modular light fixture may further comprise at least one environmental sensor located in a second housing of the second end section, the at least one environmental sensor configured to sense at least one environmental condition, and an electronic control circuit located in the second housing, the electronic control circuit configured to receive a signal indicative of the at least one environmental condition sensed by the at least one environmental sensor. In some embodiments, the modular light fixture may further comprise at least one control conductor configured to communicate signals between the first end section and the second end section.

The present disclosure also describes a method of assembling a modular light fixture. The method, according to some embodiments, comprises providing a first end section having a first housing, a first lamp holder, a first clip, and a second clip, providing a second end section having a second lamp holder, a third clip, and a fourth clip, installing a ballast in an interior of the first housing, attaching a reflector to the first clip and the second clip of the first end section, attaching the reflector to the third clip and the fourth clip of the second end section, connecting a first end of a lamp to the first lamp holder of the first end section, and connecting a second end of the lamp to the second lamp holder of the second end section.

The method may further comprise installing the first end second, second end section, and reflector in an enclosure to form a unitary structure. The method may further comprise installing at least one environmental sensor in an interior of a second housing of the second end section, the at least one environmental sensor configured to sense at least one environmental condition, and installing an electronic control circuit in the interior of the second housing, the electronic control circuit configured to receive a signal indicative of the at least one environmental condition sensed by the at least one environmental sensor. The method may further comprise attaching at least one control conductor between the electronic control circuit and the ballast.

### BRIEF DESCRIPTION OF THE DRAWINGS

The objects and advantages of the invention will be apparent upon consideration of the following detailed description, taken in conjunction with the accompanying drawings, in which like reference characters refer to like parts throughout, and in which:

FIG. 1 is a top view of a typical light fixture;

FIG. 2 is an elevational view taken along lines 2-2 shown in FIG. 1;

FIG. 3 is a perspective view of an apparatus in accordance with the present disclosure;

FIG. 4 is a perspective view of other apparatus in accordance with the present disclosure;

FIG. 5 is a perspective view of additional apparatus in accordance with the present disclosure;

FIG. 6 is a perspective view of additional apparatus in accordance with the present disclosure;

FIG. 6A-6C show perspective, top, and frontal views, respectively, of the apparatus shown in FIG. 6 with a cover removed;

FIG. 7 is a perspective view of an apparatus in accordance with the present disclosure;

FIG. 8 is a perspective view of the apparatus shown in FIG. 7;

FIG. 9 is a perspective view of additional apparatus in accordance with the present disclosure;

FIG. 10 is a perspective view of other apparatus in accordance with the present disclosure;

FIG. 11 is a partial cross-sectional view taken along line 11-11 shown in FIG. 10.

FIG. 11A is a perspective view of apparatus shown in accordance with the present disclosure;

FIGS. 12A and 12B are sectional views taken along line 12-12 shown in FIG. 11A;

FIGS. 13 and 13A are exploded perspective views of additional apparatus in accordance with the present disclosure;

FIGS. 14A, 14B and 14D are cross sectional views of apparatus in accordance with the invention. FIG. 14C is a partial cross-sectional view of apparatus in accordance with the present disclosure. FIG. 14E is a frontal view of additional apparatus in accordance with the present disclosure;

FIGS. 15A and 15B are frontal and side views, respectively, of a lamp holder that may be incorporated into any of the embodiments shown in FIGS. 3-6;

FIGS. 16A-16C show top, front, and side views, respectively, of a cover which may be used with any of the embodiments of the invention;

FIG. 17 is a schematic diagram of an apparatus in accordance with the present disclosure;

FIG. 18 is a perspective view of other apparatus in accordance with the present disclosure;

FIG. 19 is a different perspective view of the apparatus shown in FIG. 18;

FIG. 20 is a side view, corresponding to the view along line A-A shown in FIG. 17, of apparatus in accordance with the present disclosure;

FIG. 21 is a perspective view of other apparatus in accordance with the present disclosure;

FIG. 22 is a top view of the apparatus shown in FIG. 21;

FIG. 23 is a partial cross-sectional view taken along line 23-23 shown in FIG. 22; and

FIG. 24 is a perspective view of still other apparatus in accordance with the present disclosure;

FIG. 25 is a perspective view of a ballast end in accordance with the present disclosure;

FIG. 26 is a perspective view of another ballast end in accordance with the present disclosure;

FIG. 27 is a frontal view of the apparatus shown in FIG. 26;

FIG. 28 is a plan view of the apparatus shown in FIG. 26;

FIG. 29 is an exploded perspective view of the apparatus shown in FIG. 26;

FIG. 30 is a perspective view of a dummy end in accordance with the present disclosure;

FIG. 31 is a perspective view of another dummy end in accordance with the present disclosure;

FIG. 32 is a frontal view of yet another dummy end in accordance with the present disclosure;

FIG. 33 is a plan view of the apparatus shown in FIG. 32;

FIG. 34 is an exploded perspective view of the apparatus shown in FIG. 32;

FIG. 35 is a perspective view of an arrangement of a ballast end and a dummy end in accordance with the present disclosure;

FIG. 36 is a perspective view of the apparatus shown in FIG. 34;

FIG. 37 is a perspective view of another arrangement of a ballast end and a dummy end in accordance with the present disclosure;

FIG. 38 is a perspective view of yet another arrangement of a ballast end and a dummy end in accordance with the present disclosure;

FIG. 39 is a perspective view of a retrofit ballast end in accordance with the present disclosure;

FIG. 40 is a partial cross-sectional view of the apparatus shown in FIG. 39;

FIG. 41 is a plan view of the apparatus shown in FIG. 39;

FIG. 42 is a perspective view of another ballast module in accordance with the present disclosure;

FIG. 43 is a perspective view of a lamp holder module in accordance with the present disclosure;

FIG. 44 is a perspective view of yet another ballast module in accordance with the present disclosure;

FIG. 45 is a perspective view of yet another lamp holder in accordance with the present disclosure;

FIG. 46 is a block diagram of a network of light fixtures in accordance with the present disclosure;

FIG. 47 is a perspective view of a further lamp holder module with an emergency backup power supply in accordance with the present disclosure;

FIG. 48 is a perspective view of another arrangement of components of a light fixture in accordance with the present disclosure;

FIG. 49 is a perspective view of a first end of the arrangement of FIG. 48;

FIG. 50 is a perspective view of a second end of the arrangement of FIG. 48;

FIG. 51 is a perspective view of another arrangement of components of a light fixture in accordance with the present disclosure; and

FIG. 52 is a perspective view of the arrangement of FIG. 51.

### DETAILED DESCRIPTION OF THE INVENTION

Apparatus and methods of manufacture for a ballast module for a fluorescent lamp fixture are provided. The apparatus may include a ballast housing. The apparatus may also include a lamp holder configured to be coupled to the ballast housing. A ballast may be at least partially enclosed within the ballast housing.

The lamp holder may be configured to hold one end of a tube-shaped lamp. In some embodiments of the invention, the lamp holder may be in electrical communication with a conductor such that when the lamp holder supports a lamp, the lamp holder is able to provide power from the conductor to the lamp.

When long tubes are used, two opposing lamp holders (one at each end of the lamp) are generally required--one to support and excite each end of the lamp. In embodiments in which a short or “single-ended” fluorescent lamp is used, one lamp holder for the lamp may be sufficient. It should be noted that the lamp holder may be configured to support any suitable lamp, including the T5, T8 and T12 lamps. In some embodiments, the lamp holder may be configured to support an LED lamp. In those embodiments where the lamp holder is configured to support an LED lamp, a LED driver circuit may substitute for a ballast. In some embodiments, the lamp holder may be configured to support a U-shaped lamp.

Some embodiments of the invention may include modules that may be fastened to a lamp fixture enclosure. The lamp fixture enclosure may be referred to alternately throughout the disclosure as a fixture housing. The ballast module may be fastened to the lamp fixture enclosure. A lamp holder module containing at least one lamp holder may also be fastened to the lamp fixture enclosure.

The ballast module may be arranged at one end of the lamp fixture enclosure. The lamp holder module may be arranged opposite the ballast module at the other end of the lamp fixture enclosure. In some embodiments, a second ballast module may be arranged opposite the first ballast module at the other end of the lamp fixture enclosure. Because the ballast module includes at least one lamp holder, the need for wiring between the ballast enclosed in the ballast module and the lamp holder may be reduced or eliminated. Some embodiments of the invention may include a ballast and lamp holder with a wireless connection therebetween. For example, the wiring that is present in a typical lamp fixture may be replaced by a conductor that is integrated into a structural element of the ballast. The lamp holder may be in electrical connection with the conductor integral on the ballast to create a wireless electrical connection. In other embodiments, one or more wires may be used to transmit power from the ballast to the lamp holder.

The lamp holder may be removably coupled to the ballast module and/or the lamp holder module. In some embodiments of the invention, the lamp holder may be removably coupled to the wires that transmit power from the ballast module to the lamp holder. In addition, the ballast module and/or the lamp holder module may be removable from the lamp fixture enclosure. Removable modules may facilitate repair, replacement and/or reconfiguration of the fluorescent tube pattern. In some embodiments, the repair, replacement and/or reconfiguration may take place at the point of manufacture. In other embodiments, the repair, replacement and/or reconfiguration may take place in the field.

The ballast enclosed in the ballast housing may receive power from a standard power line, such as a 110 VAC power line or any other suitable power line. The ballast may include a reactive coil and a power conditioner for providing appropriate current to the lamp.

A conductor that is configured to transmit electrical power from the ballast to the lamp holder may be enclosed within the ballast housing as well. The conductor may be part of a rigid power distribution unit. In this embodiment, the conductor may be rigidly supported substantially continuously along its length.

In some embodiments of the invention, the conductor may be part of a continuous bus. The continuous bus may be configured such that one or more lamp holders may be placed at any location along the bus. A lamp holder electrical connector may mate with the continuous bus through clamping, press fit, mating, or any other suitable means. The lamp holder may be removably connected to the continuous bus.

The conductor may be included in a printed circuit board (“PCB”). The rigid power distribution unit may include the printed circuit board. The printed circuit board may have traces from each lamp holder to be plugged into it. The printed circuit board may be part of a ballast printed circuit board assembly.

The lamp holder printed circuit board may be connected to the ballast by any suitable connectors, such as male/female connectors. The ballast may be located either inside or outside a housing that may enclose the rigid power distribution unit.

The lamp holder may clamp or be otherwise mechanically and electrically secured to the printed circuit board and draw power from it. The printed circuit board may be in electrical communication with the lamp holder via flat cable and male/female connectors. In some embodiments, the lamp holder may be connected to the PCB by soldering. The lamp holder may be removably connected to the PCB via male/female connectors, pin and sleeve connectors, or any other suitable connectors. Lamp holder electrical connectors may mate with the PCB through clamping, press fit, mating, or any other suitable means.

In some embodiments, the lamp holder may be slidably connected to the PCB via a slidable contact brush, a leaf spring or any other suitable slidable contact. In these embodiments, one or more detents may be provided to position the lamp holder at one of a series of positions. The series of positions may be regular intervals. The regular intervals may be spaced apart by any suitable distance, such as 0.25 inch.

In some embodiments, the rigid power distribution unit may include a track that has conducting rails for supplying power to lamp holders. The rigid power distribution unit may include a housing. The housing may be made of plastic, metal or other suitable enclosure material.

The rails may be made of any suitable conducting metal such as copper, silver, brass or the like. For example, the conducting metal may be an abrasion-resistant metal, such as brass.

The track may be open on one or both ends for insertion of a lamp holder. An open end of the track may be blocked by a skirt after insertion of one or more lamp holders. The skirt may include any suitable material, such as a polymer or elastomer such as ethylene acrylic elastomer (“AEM”) such as that available under the trademark “VAMAC” from E. I. DuPont and Co., located in Wilmington, Del. The material may be an elastomer, such as neoprene. It should be noted that skirt may be removably connected to the open end of the track, allowing for the removal and/or addition of lamp holders during manufacture and/or in the field.

The rails may run along a portion of the track so that lamp holders engaging a portion of the track may receive power from the rails. The track may include a slot or edge along which the lamp holders may slide. The track may include one or more detents to maintain a lamp holder in a position along the track. In manufacturing, the track may be used to position lamp holders at any desired spacing so the track may be used in connection with fixture designs requiring different center-to-center lamp spacing. The spacing may optionally be standardized to accommodate one or more of the various industry standards.

Upon completion of the positioning of the lamp holder, the lamp holder may be permanently fixed in position after assembly. The lamp holder may be fixed in position by welding, soldering, crimping, buttressing or by any other suitable approach. Alternatively, the lamp holder may be held in place by the one or more detents or by any other suitable means. In this embodiment, the position of the lamp holder may be adjusted at a later point in time.

The aforementioned embodiments taught by the disclosure may allow for one or more lamp holders to be adjustably positioned on the ballast module. This may provide a manufacturer with the ability to use a single fixture type for more than one fluorescent tube configuration or any other desirable lamp configuration. Different configurations may be based on the different sizes and numbers of lamps such as T5, T8 and T12 style fluorescent lamps, which are commonly used in the electrical industry, in addition to any other suitable lamps.

A fixture may be fitted with one or more of several different modules having different ballasts or different lamp holder configurations.

The ballast housing may include a slotted opening that is configured to receive a portion of the lamp holder. One or more contacts or traces may be disposed inside the slotted opening to electrically communicate with the lamp holder. The contacts or traces may be in electrical communication with the ballast. The contacts or traces may be in electrical communication with the ballast via the PCB or any other suitable means. The electrical communication may involve the use of a male/female connector, a pin and sleeve connector, and/or soldering to the PCB.

The ballast housing may also include a top cover. The top cover may include one or more openings to provide various lamp holder numbers and configurations. For example, the openings may accommodate any number of lamp holders, such as 2-6 lamp holders.

The lamp holder may snap and lock into place on the top cover of the unit in such a manner as to allow for quick and easy replacement. In some embodiments, the lamp holder may be mounted on a different aspect of the ballast housing, such as a front, back or end of the ballast housing.

In some embodiments of the invention, lamp holders may be connected to the ballast housing. The lamp holders may be soldered to the ballast housing and/or form a unitary structure with the ballast housing. In some embodiments of the invention, the lamp holders may be removably coupled to the ballast housing.

The ballast housing may enclose a printed circuit board with ballast components mounted to the printed circuit board. These ballast components may extend away from the printed circuit board. The printed circuit board may be disposed on a base metal housing covered by the ballast housing. In embodiments having lamp holders that are configured to support an LED lamp, the printed circuit board may support one or more LED driver components in place of ballast components.

The ballast components may include an instant start ballast component or a rapid start ballast component or a programmed rapid start ballast component. In some embodiments of the invention, the printed circuit board may include a dimming ballast component, an emergency ballast component and/or a switching ballast component.

In some embodiments of the invention, the ballast housing may include an occupancy sensor and/or a daylight sensor or both. In embodiments that include an occupancy sensor, the ballast components may include an occupancy sensor component. In embodiments that include a motion sensor, the ballast components may include a motion sensor component.

The ballast components may be clustered together in the center of the printed circuit board, on the two ends of the printed circuit board, or at suitable intervals along the length and/or width of the printed circuit board. The ballast housing may extend above the ballast components and the printed circuit board.

The printed circuit board may be disposed on a base of the housing. The printed circuit board may have a bottom face that faces the base. The printed circuit board may have a top face that faces away from the base. The ballast components may be mounted on the top face and extend away from the housing base. The housing may have a top that is spaced apart from the printed circuit board at a distance that varies in conformance with the sizes of one or more of the components. For example, the distance may be enough to provide clearance for components where components are present on the printed circuit board. In regions of the printed circuit board where components are small or not present, the distance may be reduced.

The one or more lamp holders integrally molded into the ballast housing may be in electrical communication with one or more of the ballast components. In some embodiments, wire connectors may connect the one or more lamp holders to the one or more ballast components. In other embodiments, the lamp holders may be connected to the one or more ballast components via flat cable and male/female connectors. In other embodiments, the lamp holders may be connected to the printed circuit board through traces in the printed circuit board.

One or more line power connection leads and/or emergency ballast connection leads may exit the ballast module housing. Some or all of these leads may exit through an opening located in the front face of the mid-section of the ballast housing. Some or all of these leads may exit through an opening located at a side of the ballast housing, or in any other suitable location. The leads may be in electrical communication with a power source, such as a 120V outlet.

In embodiments of the invention that include lamp holders that are integrally molded to the ballast housing, the lamp holder module may contain a lamp holder housing with one or more lamp holders. The one or more lamp holders may be integrally molded into the lamp holder housing such that the lamp holders and a portion of the lamp holder housing form a unitary structure. In other embodiments, the lamp holders may be removably coupled to the lamp holder housing. The one or more lamp holders connected to the lamp holder housing may be in electrical communication with a conductor. The conductor may be a wire. The wire may connect to the ballast module. The wire may connect the lamp holders in series or in parallel.

The ballast module and the lamp holder module may be spaced a distance apart. The distance apart may correspond to a nominal fluorescent lamp length. This distance may enable the ballast module and the lamp holder module to support one or more fluorescent lamps therebetween. The center-to-center distance between the lamp holders included in the ballast module and the lamp holders included in the lamp holder module may be fixed.

The ballast housing and the lamp holder housing may be comprised of a thermoplastic material or any other suitable material. The ballast housing and the lamp holder housing may include one or more fastening features. The one or more fastening features may enable the ballast housing and the lamp holder housing to be fixed to a fixture housing.

The fastening feature may be a screw hole, a snap-fixture, a slot, a tab or any other suitable fastening feature. When the fastening feature is a screw hole, the screw hole may be a metal tab, captive screw and/or any other suitable holes that facilitate the attachment of the ballast housing and the lamp holder housing to a fixture housing.

The ballast module and the lamp holder module may be spaced apart so that a fluorescent lamp can be supported therebetween. The lamp holders in the ballast module and the lamp holder module may include a lamp pin guide. The lamp pin guide may alternately be referred to as a rotor. The rotor may be used to support a linear fluorescent lamp therebetween.

In embodiments that are configured to support a U-shaped lamp, the ballast module and the lamp holder module may be placed adjacent to each other. In the embodiment of the U-shaped lamp, the lamp holders contained in the ballast module and the lamp holder module may include two straight slots to support the fluorescent lamp therebetween.

In some embodiments of the invention, the ballast module and the lamp holder module may be connected by a single lead that exits at either end of the modules. In other embodiments, the ballast module and the lamp holder module may not be in direct electrical communication.

In some embodiments of the invention, the ballast module may be configured to replace a previously installed ballast module. The previously installed ballast module may be removed, and the ballast module subsequently fixed to the fixture enclosing. In these embodiments, the ballast module and the lamp holder module may alternately be referred to as a retrofit ballast module and a retrofit lamp holder module.

The retrofit ballast module may produce more light using less energy than the previously installed ballast module. In these embodiments, the retrofit ballast module and the retrofit lamp holder module may be configured to support a lamp such as the T5 lamp, whereas the previously installed ballast module and lamp holder module were configured to support at T8 lamp.

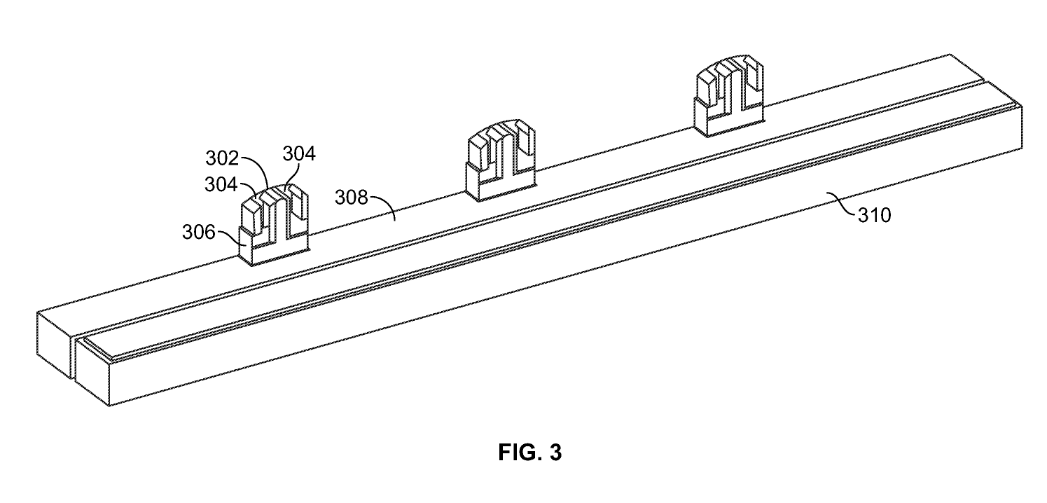

FIGS. 3-52 show illustrative embodiments and features of the invention.

FIG. 3 shows illustrative body 308. Three lamp holders 302 are attached to body 308. Body 308 may be a ballast module. Body 308 may be a unitary structure and may be made of a non-conductive material. Alternatively, body 308 may be made from an assembly of parts. In the present embodiment, body 308 is assembled onto a PCB and includes apertures configured to receive and support lamp holders 302. Enclosure 310 encloses the PCB which may be constructed of sheet metal. Body 308 is dimensioned such that, when assembled, the lamp holders 302 are supported and enclosed with no access to live parts.

Lamp holders 302 may include one or more electrical contacts configured to conduct electricity from lamp holder 302 to one or more lamps installed in lamp holder 302. Each lamp holder may include slots 304 which allow for pins of fluorescent lamps to engage with the electrical contacts. It should be noted that the systems and methods of the invention include lamp holders of any suitable configuration (including, for example, the rotary lamp holders shown in FIG. 9).

Body 308 may at least partially contain a conductive bus, a ballast, wiring, or any combination of one or more of these elements. Lamp holders 302 may be removable from body 308 for replacement, repair, or reconfiguration during manufacture and/or in the field.

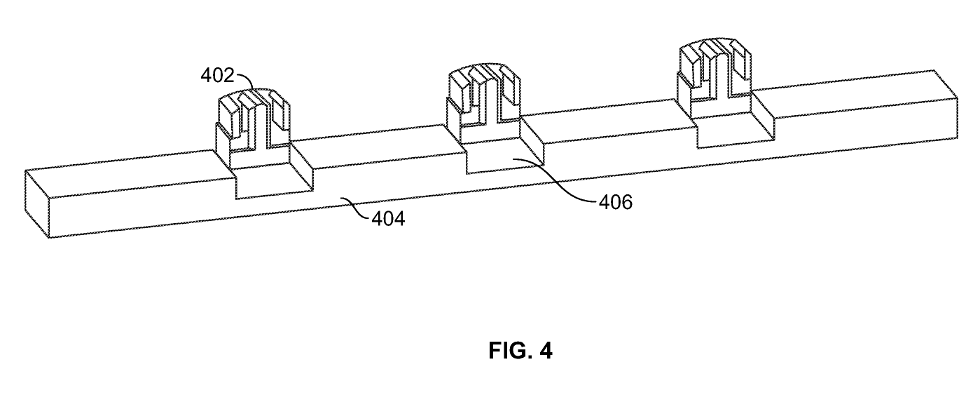

FIG. 4 shows illustrative body 404. Body 404 may include one or more depressions 406. Depressions 406 may be adjacent to one or more lamp holders 402. Depressions 406 may allow for shorter lamp holders 402 to be inserted into body 404 resulting in a thinner overall profile of the fixture. This is advantageous in certain installations when space is limited.

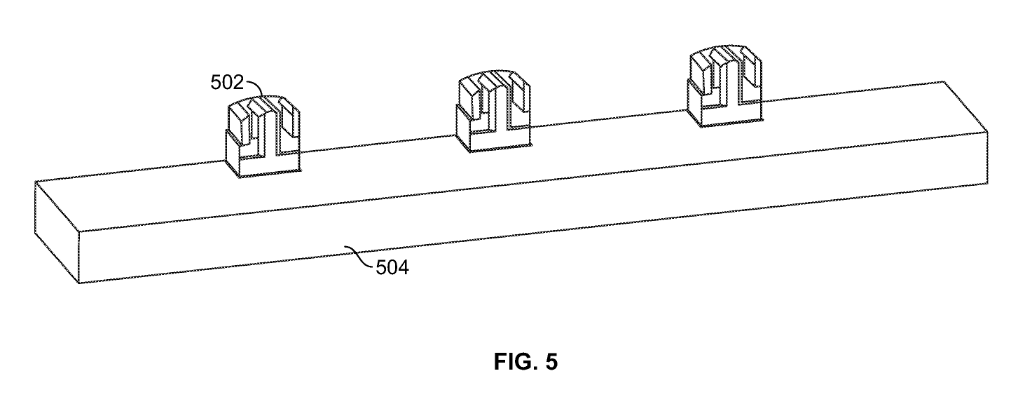

FIG. 5 shows illustrative body 504. Lamp holders 502 are attached to body 504, wherein the attachment provides an electrical connection therebetween.

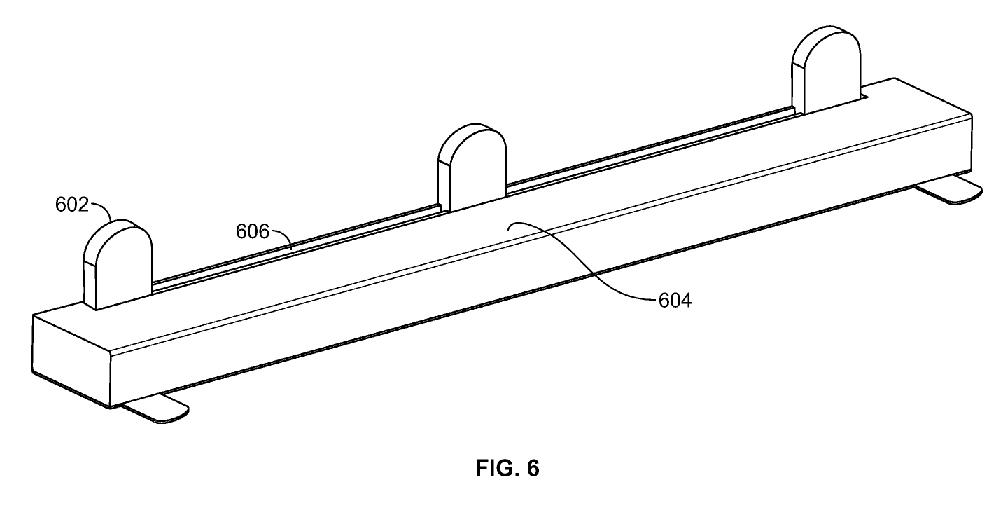

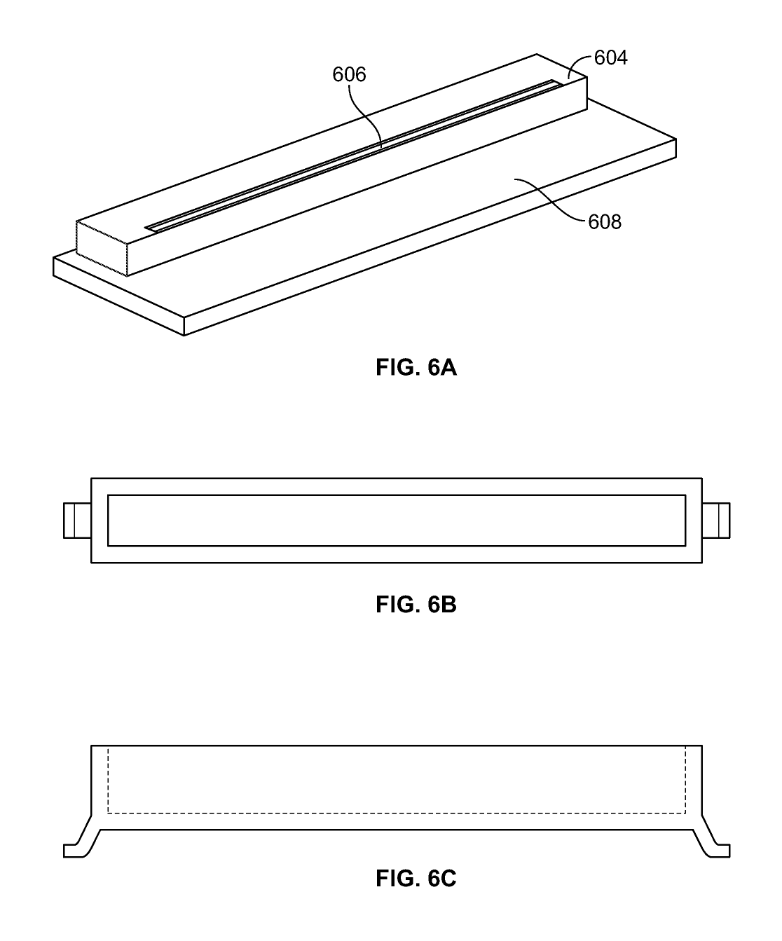

FIG. 6 shows illustrative body 604. Slot 606 in body 604 allows for one or more lamp holders 602 to be installed in body 604 at any point along slot 606. An electrical bus may run along the length of body 604, allowing the lamp holders to be placed at any point along slot 606.

In some embodiments of the invention, slot 606 may include fixed points (not shown) in which lamp holders 602 may be installed. The fixed points may be located at any suitable interval along slot 606, such as 0.25 inch along the length of slot 606.

FIG. 6A shows that PCB 608 may be located below body 604. The bus may take the form of a trace along PCB 608. Contact points may be located below slot 606 to connect to lamp holders 602. In addition, optional detents may be included in the housing, on the PCB, or on any other suitable member in order to positively locate the lamp holders at regular intervals along the bus.

FIG. 6B shows a top view of body 604 without lamp holders 602 and with the cover of body 604 removed. FIG. 6C shows a side view of body 604 without lamp holders 602 and with the cover of body 604 removed.

FIG. 7 shows illustrative body 704. Each lamp holder 702 includes a leg 708 which is disposed perpendicularly to the main lamp holder body 710. In this embodiment, the lamp holder exits along side face 706 of the body instead of along top face 704.

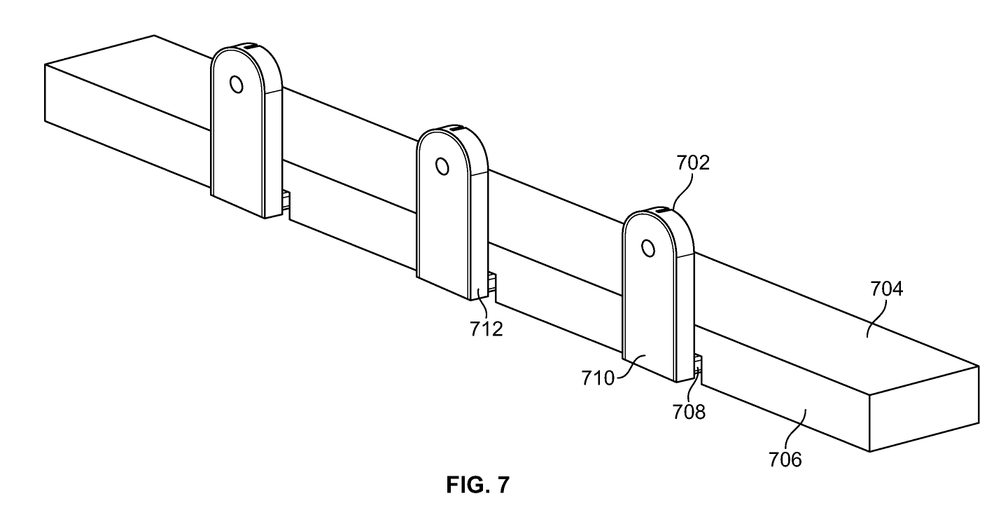

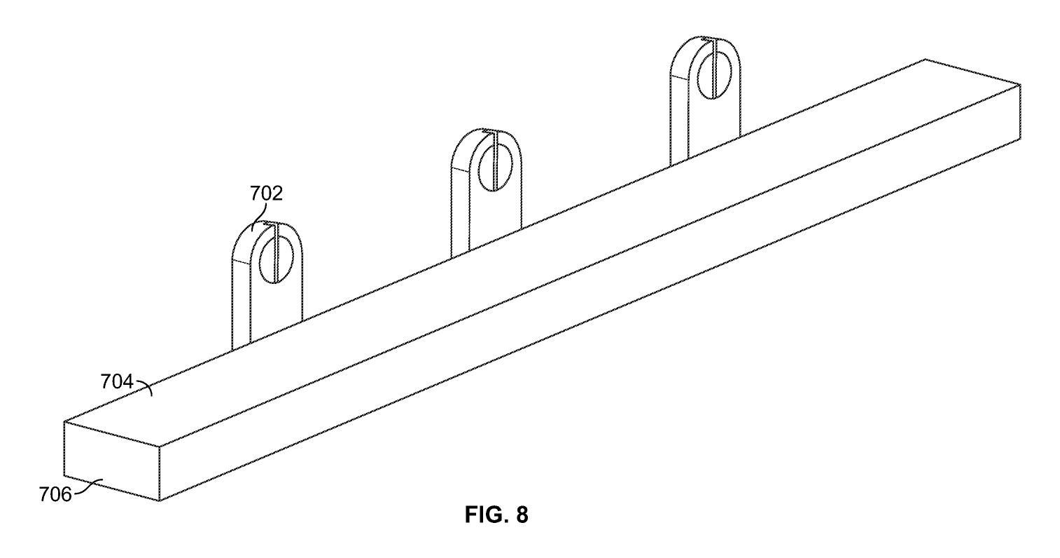

FIG. 8 shows a perspective view of body 704.

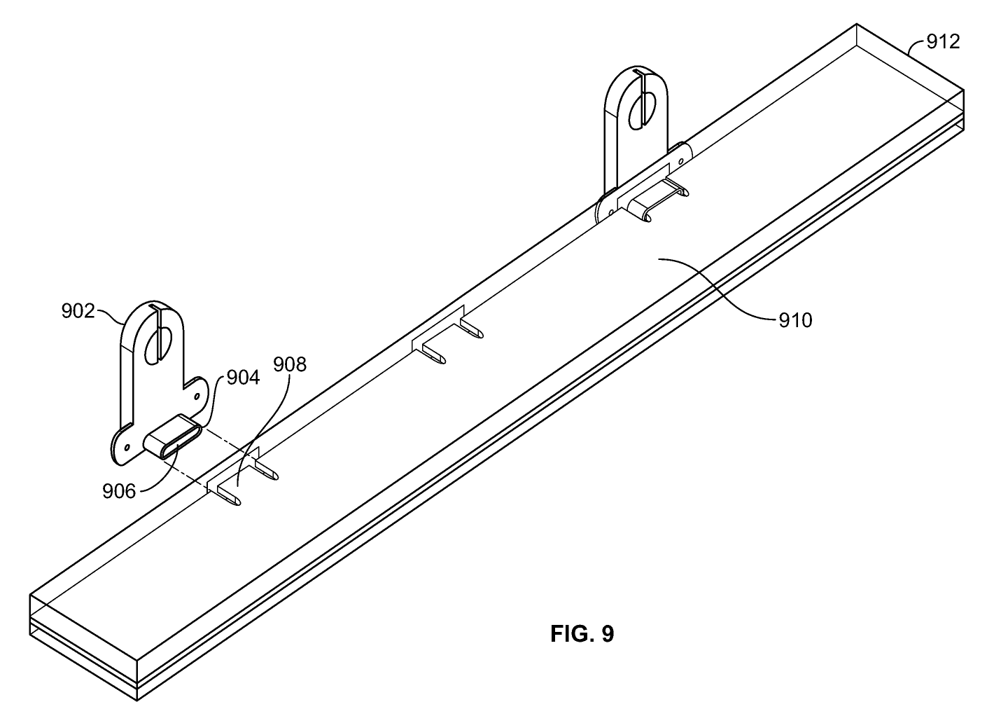

FIGS. 9 and 10 show illustrative PCB 910 with a portion of housing 912 removed to show internal components. PCB 910 is at least partially enclosed within housing 912. PCB 910 may support a ballast. PCB 910 may include one or more PCB tabs 908 which are disposed to engage opening 906 of leg 904 of lamp holder 902. A contact may be located on PCB tab 908. The contact may be a trace on PCB 910. The contact may provide power to lamp holder 902.

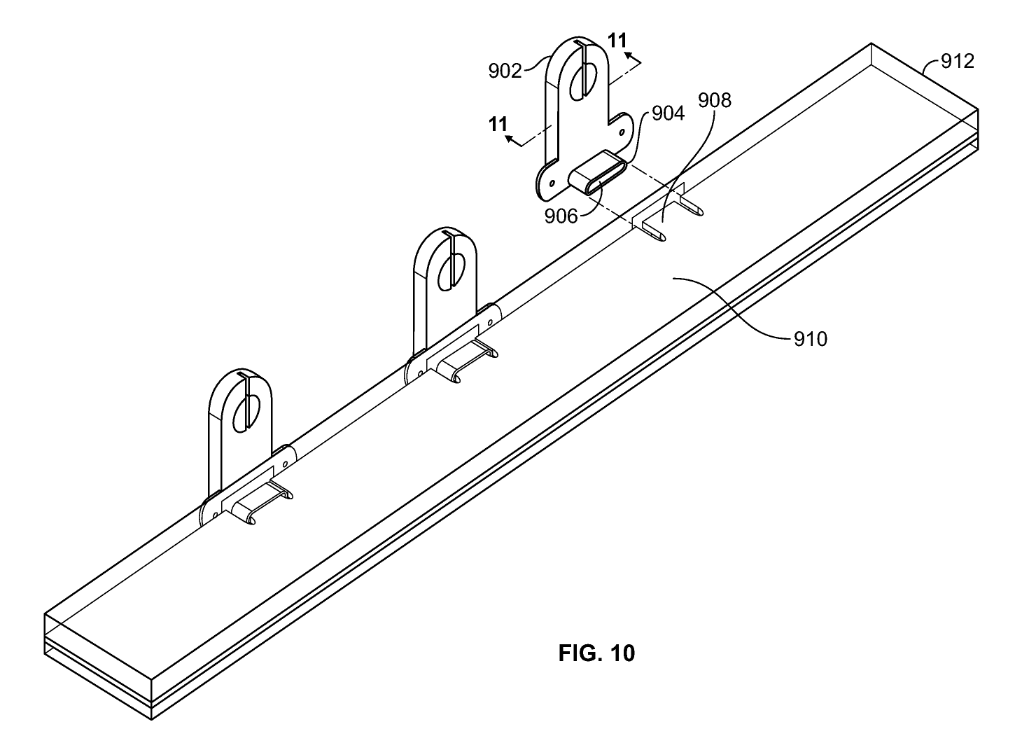

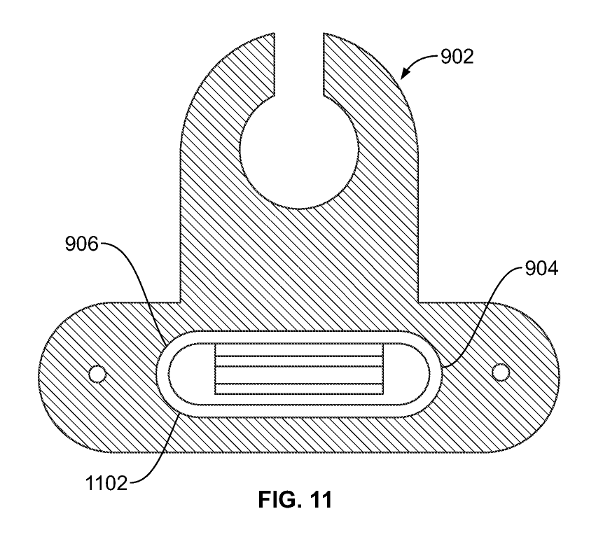

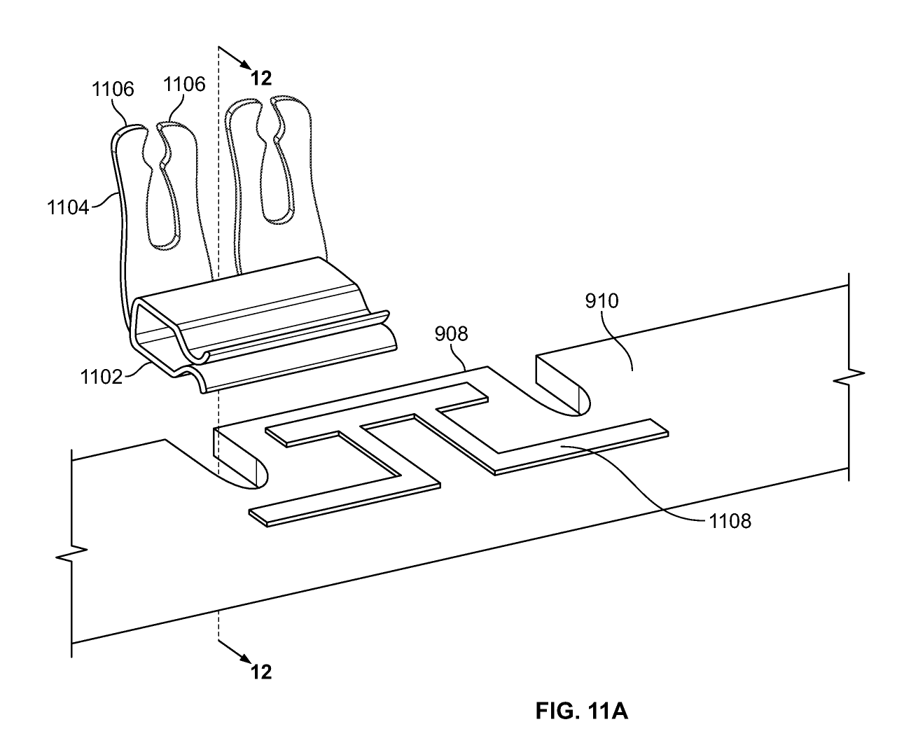

FIG. 11 illustrates a partial cross sectional view along line 11-11 shown in FIG. 10 of illustrative lamp holder 902 with leg 904 and opening 906. FIG. 11 further illustrates sleeve 1102 that is configured to make electrical contact with a PCB, as further illustrated in FIG. 11A.

FIG. 11A illustrates a detailed view of a contact 1104 that is contained in illustrative lamp holder 902. Contact 1104 may include one or more tines 1106 that are disposed to connect to pins of a lamp. Contact 1104 may additionally include sleeve 1102. Sleeve 1102 may be disposed to slide over PCB tab 908 and make electrical contact with conductor 1108. Conductor 1108 may be a trace on PCB 910.

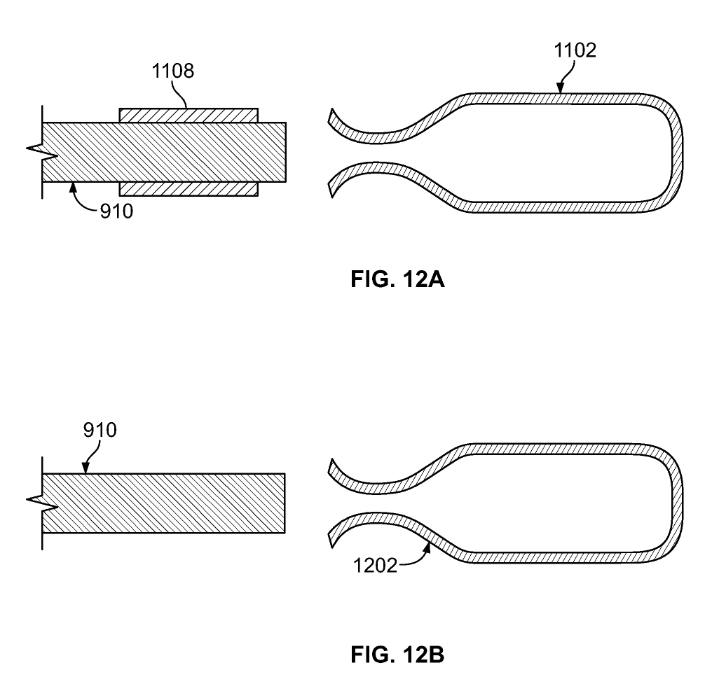

FIGS. 12A and 12B show sections taken along line 12-12 shown in FIG. 11A. FIG. 12A illustrates a cross sectional view of sleeve 1102 and a cross sectional view of conductor 1108 disposed along the top and bottom surfaces of PCB 910. FIG. 12B illustrates an alternate contact geometry of the contact geometry illustrated in FIG. 12A that is included in some embodiments of the invention.

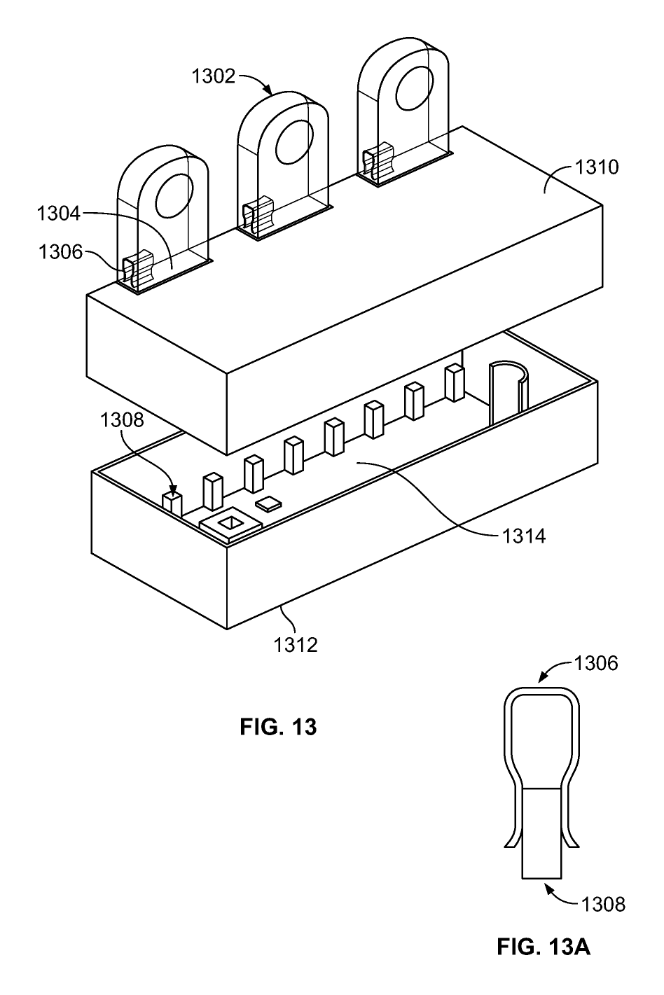

FIG. 13 shows illustrative body 1310. Lamp holder 1302 may be removably attached to body 1310. Lamp holder 1302 may be easily assembled and removed from body 1310 for replacement, repair and/or reconfiguration. In some embodiments of the invention, lamp holder 1302 may be a lamp holder that has a locking feature (not shown). The locking feature of lamp holder 1302 may be a snap hook arm. The locking feature, when depressed, may unhook the lamp holder from body 1310 without the need of a special tool.

Body 1310 may include apertures 1304 to receive one or more lamp holders 1302. PCB 1314 may be at least partially disposed within body 1310. In some embodiments of the invention, a ballast and/or additional electrical components may be disposed in body 1310 as well. PCB 1314 may include pin 1308. Pin 1308 may engage sleeve 1306 of lamp holder 1302. The engagement of pin 1308 with sleeve 1306 may provide power from PCB 1314 to lamp holder 1302. Pins 1308 may be spaced at regular intervals such as 0.25 inches and may have a cross-section of any suitable shape and size such as 0.062 inch round pins. Sleeves 1306 may be of any suitable shape and size such as having a gap in the sleeve of 0.030 inches. In addition, the PCB may be of any suitable shape or size such as having a thickness of 0.062 inches.

While the pins and sleeves shown in FIG. 13 provide power from PCB 1314 to lamp holders 1302, any suitable mating electrical connectors may be used. In some embodiments of the invention, lamp holders 1302 may include pins and the PCB may include sleeves, wherein the mating of the pins to the sleeves provides electrical power from PCB 1314 to lamp holder 1302.

FIG. 13A shows a cross sectional view of sleeve 1306 of illustrative lamp holder 1302 when mated to pin 1308 of PCB 1314. The mating of sleeve 1306 to pin 1308 may create an electrical connection therebetween.

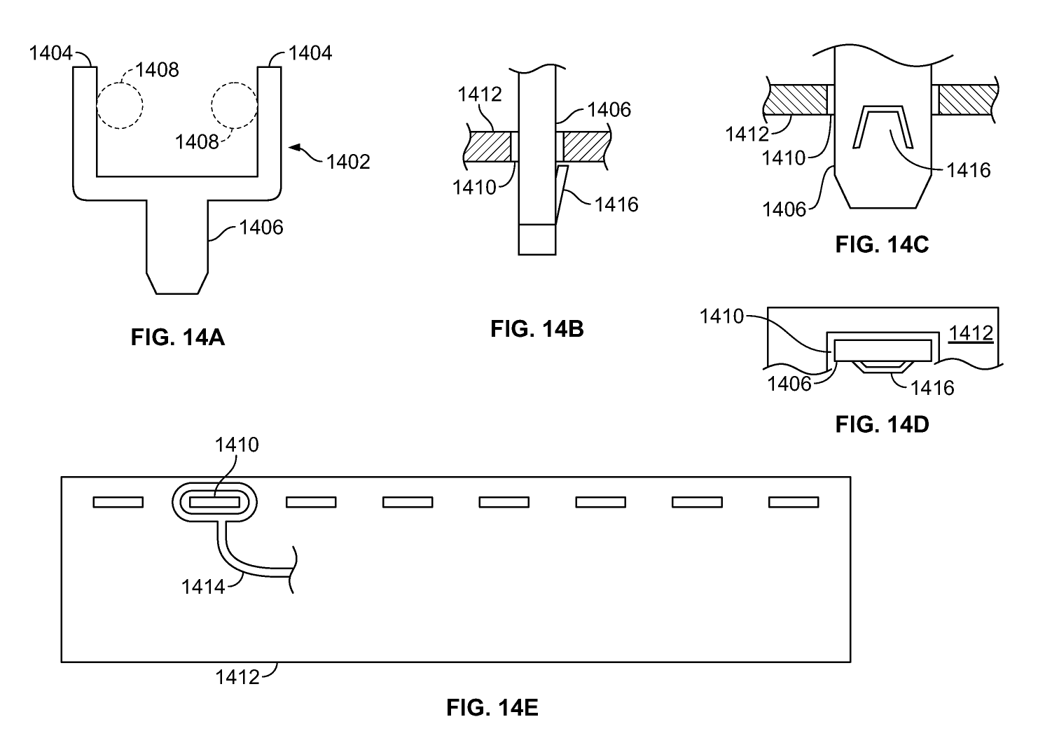

FIGS. 14A-14D show illustrative tang 1406 that may be located on contact 1402 of a lamp holder taught by the invention. Contact 1402 may contain one or more tines 1404 configured to contact pins 1408 of a lamp. Contact 1402 may additionally contain conductive tang 1406.

FIG. 14E shows illustrative PCB 1412. Conductive tang 1406 may be configured to connect to PCB 1412. PCB 1412 may have one or more openings 1410 configured to receive tang 1406. Tang 1406 may include tab 1416. Tab 1416 may be configured such that, when tang 1406 is inserted into opening 1410, tang 1406 latches in place. Tang 1406 may then be electrically connected to PCB 1412. In some embodiments of the invention, Tang 1406 may be soldered to trace 1414 of PCB 1412.

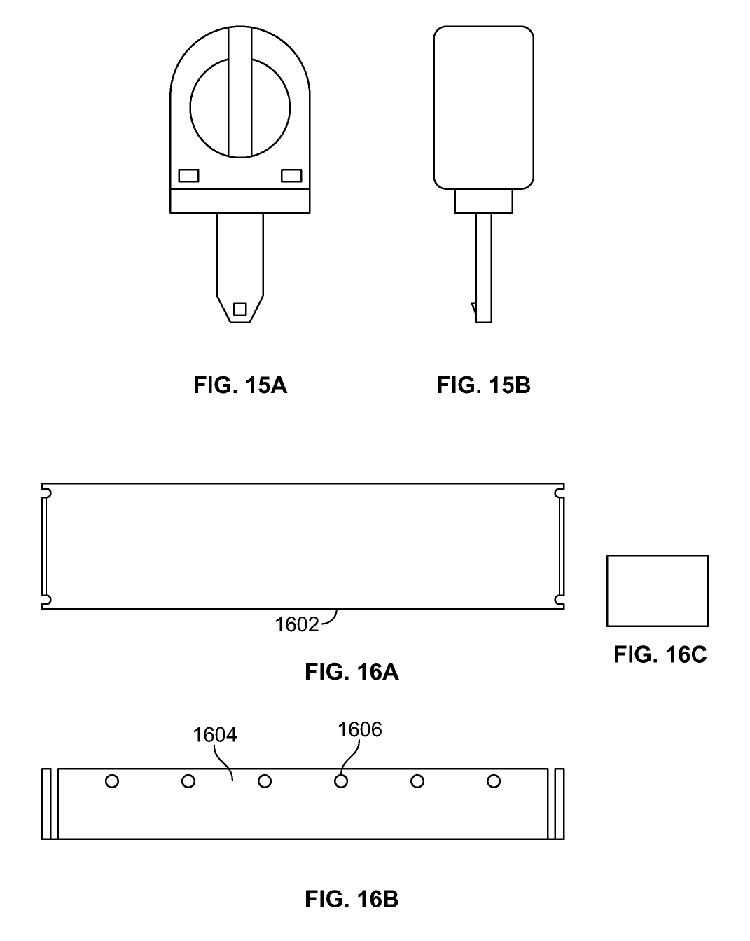

FIGS. 15A and 15B show an illustrative rotary lamp holder with its associated contact and tang that may be used in some embodiments of the invention. FIG. 15A illustrates a frontal elevational view of the rotary lamp holder. FIG. 15B illustrates a side view of the rotary lamp holder. The rotary lamp holder illustrated in FIG. 15 may be used to snap onto a PCB such as PCB 1412 illustrated in FIG. 14.

FIG. 16A shows illustrative cover 1602 which may be used to encase any of the apparatus taught by the systems and methods of the invention. FIG. 16B shows illustrative wall 1604 of cover 1602. Wall 1604 may include latching tabs 1606 which are disposed to secure the cover 1602 to other parts of the device housing. Tabs 1606 may be in the form of barbs. FIG. 16C illustrates a side view of the housing illustrated in FIGS. 16A and 16B.

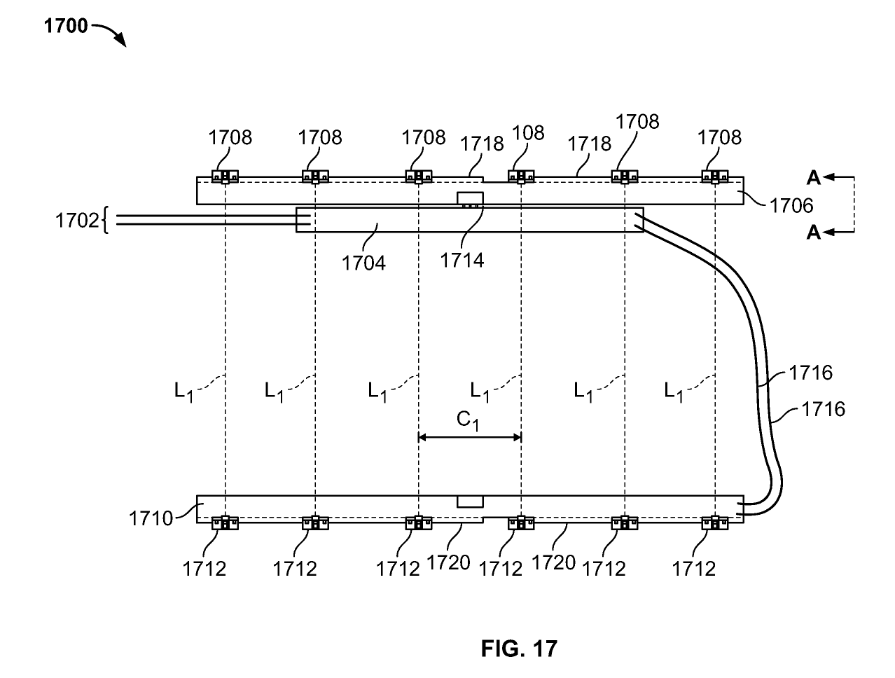

FIG. 17 shows schematically lamp support 1700. Lamp support 1700 includes power input leads 1702, ballast 1704, rigid power distribution unit 1706 and lamp holders 1708. Lamp support 1700 also includes rigid power distribution unit 1710 and lamp holders 1712. Each of lamp holders 1708 has a facing lamp holder 1712. Together, a pair of lamp holders—one 1708 and a corresponding 1712—hold a fluorescent lamp or tube at its ends. Lines L1 represent the center lines of lamps that may be installed between corresponding lamp holders. Adjacent lines L1 may be separated, for example, by center-to-center distance C1.

Rigid power distribution units 1706 and 1710 may be affixed to an enclosure (not shown). Ballast 1704 receive power via leads 1702 and provide the power to lamp holders 1708 via rigid power distribution unit 1706. Rigid power distribution unit 1706 may be connected to ballast 1704 by connector 1714. Connector 1714 may be a pin connector or any other suitable connector. Rigid power distribution unit 1710 may receive power from ballast 1704 via leads 1716.

One or both of rigid power distribution units 1706 and 1710 may include a printed circuit board for delivering power along traces or conductors to lamp holders 1708 and 1712, respectively. Positive and negative conductors, each corresponding to one of leads 1702 and one of leads 1716, may be provided along edges 1718 and 1720, respectively, of rigid power distribution units 1706 and 1710. The positive and negative conductors may match corresponding positive and negative terminals of lamp holders 1708 and 1712. The positive and negative conductors may be arranged in any suitable configuration. For example, in some embodiments, the positive and negative conductors may be, respectively, on top and bottom of edges 1718 and 1720. In some embodiments, both the positive and negative conductors both may on one side (top or bottom) of edges 1718 and 1720. The positive and negative conductors may be routed through their respective rigid power distribution units in any suitable manner to deliver power to positions on edges 1718 and 1720 where power is or may be desired. In some embodiments, power may be routed to points on edges 1718 and 1720. In some embodiments, power may be routed to elongated segments of edges 1718 and 1720. The segments may allow lamp holders 1708 and 1712 to be positioned with greater flexibility.

In some embodiments the segments may be sufficiently elongated that the lamp holder may be attached subject to an appropriate mechanical tolerance, but sufficiently restricted such that a properly installed lamp holder will shield the segment from contact with other objects. In some embodiments, the traces may be below the surface of the rigid power distribution unit. In those embodiments, the lamp holders may be provided with crimps or fasteners to make electrical contact with the traces. Rigid power distribution units 1706 and 1710 should be sufficiently rigid to mechanically support lamp holders 1708 and 1712 such that corresponding lamp holders can support and power a lamp.

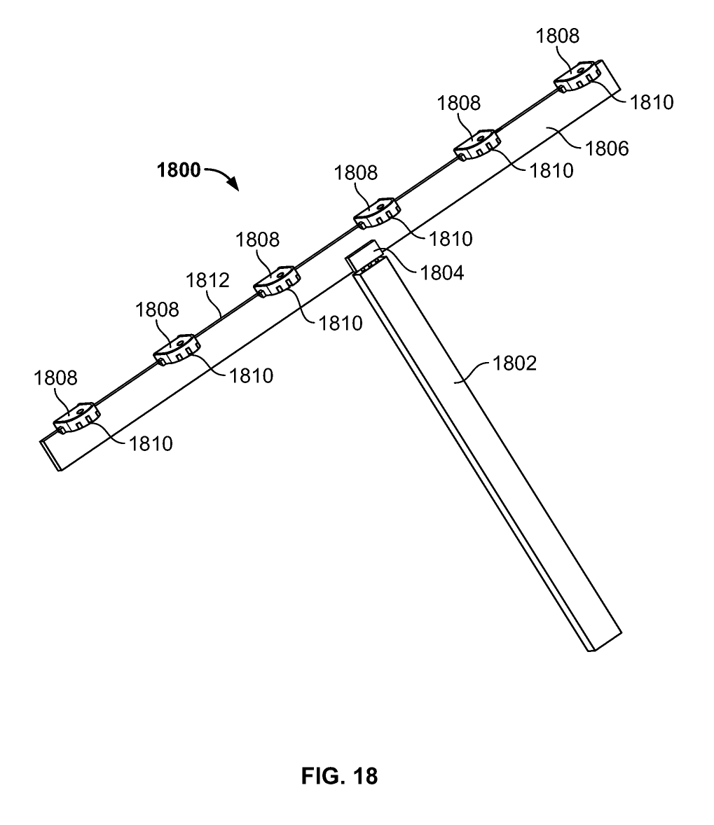

FIG. 18 shows in perspective, from below (in an operational orientation), illustrative lamp support 1800. Lamp support 1800 includes ballast 1802. Ballast 1802 connects via connector 1804 to rigid power distribution unit 1806. Rigid power distribution unit 1806 may mechanically support lamp holders 1808 via a press fit of lamp holders 1808 onto edge 1812. Edge 1812 includes conductors to provide power to electrical terminals (not shown) of lamp holders 1808. Rigid power distribution unit 1806 may be a printed circuit board that has traces that deliver power to lamp holders 1808. Lamp holders 1808 may include pin slots 1810 for receiving pins of fluorescent lamps.

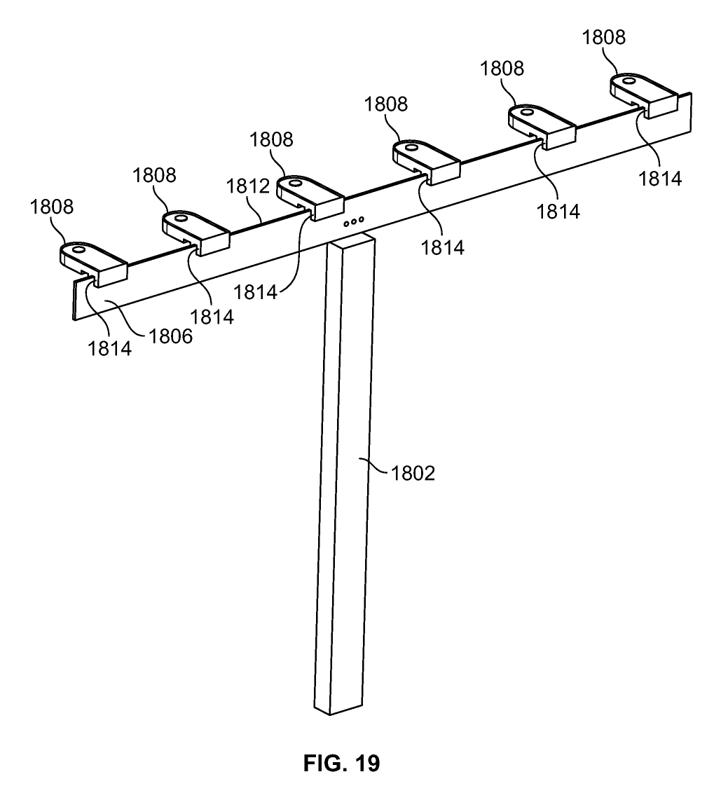

FIG. 19 shows lamp support 1800, in perspective, from above (in an operational orientation). Slots 1814 in lamp holders 1808 may be press fit onto edge 1812. Slots 1814 may include electrical terminals for transmitting power from edge 1812 to lamps, when lamps are installed in lamp holders 1808.

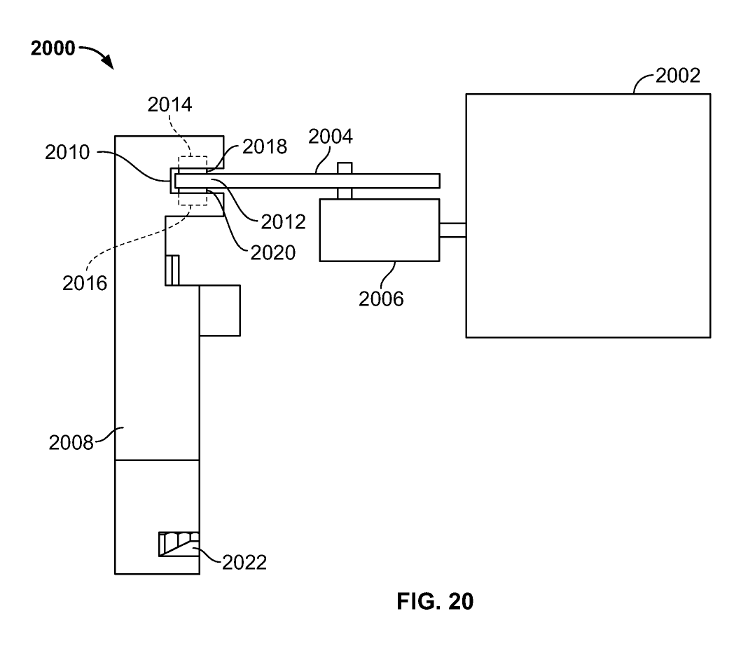

FIG. 20 shows illustrative lamp support 2000 in side view. The view shown in FIG. 20 may correspond to a side view along direction A-A, shown in FIG. 17. Lamp support 2000 includes ballast 2002. Lamp support 2000 include rigid power distribution unit 2004. Ballast 2002 and rigid power distribution unit 2004 may be electrically joined by connector 2006. Lamp holder 2008 may have groove 2010 for mating with edge 2012 of rigid power distribution unit 2004. Groove 2010 may include terminals 2014 and 2016 for contacting traces 2018 and 2020, respectively, on edge 2012. Slot 2022 may be provided for testing circuit continuity via lamp holder 2008.

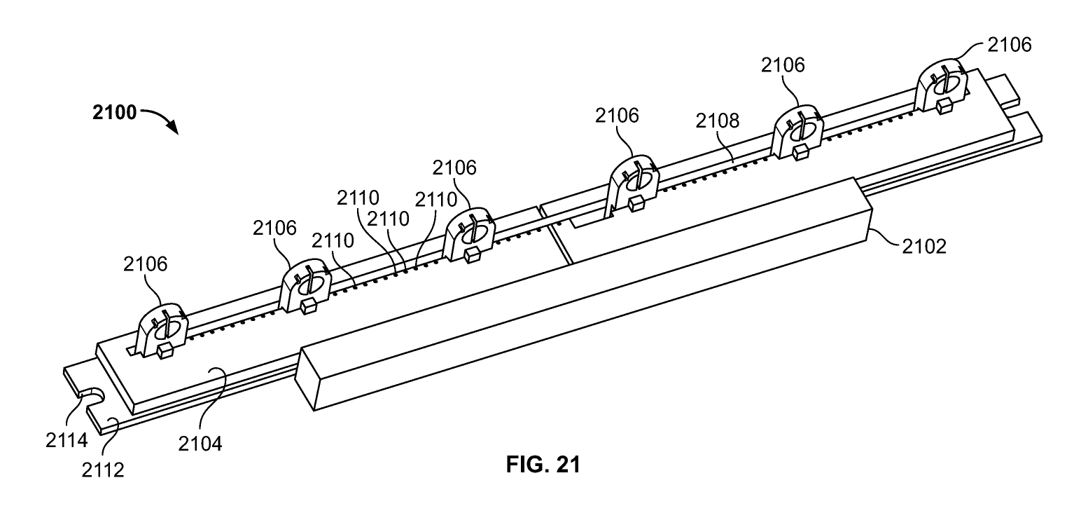

FIG. 21 shows illustrative lamp support 2100. Illustrative lamp support 2100 includes ballast 2102 and rigid power distribution unit 2104. Lamp holders 2106 are slidably mounted in track 2108 of rigid power distribution 2104. Detents, such as detents 2110, or any other suitable detents, may be present in or about track 2108 to provide determined locations at which lamp holders 2106 may be maintained. Ballast 2102 may receive power via leads (not shown). Ballast 2102 may provide power to rigid power distribution unit 2104 via a connector (not shown). Ballast 2102 may provide power to a distal power distribution unit (not shown) via leads (not shown). The distal power distribution unit may support a distal end of one or more lamps. (Rigid power distribution unit 2104 may be referred to as a “proximal” power distribution unit, because it is adjacent ballast 2102).

Rigid power distribution unit 2104 may be mounted to plate 2112. Plate 2112 may have any suitable features for attaching lamp support 2100 to a lamp enclosure (not shown) or any other suitable structure.

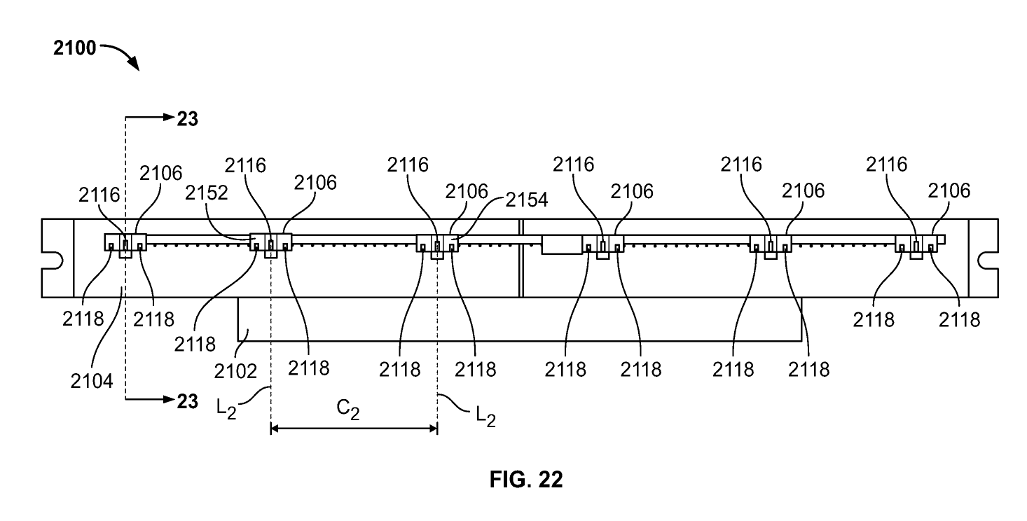

FIG. 22 shows a perspective view of lamp support 2100. Lamp holders 2106 may include slots 2116 for receiving terminal pins from a lamp. (It will be appreciated that there are different arrangements by which lamp holders may mechanically and electrically engage lamps. Any suitable lamp holder may be used in conjunction with the lamp supports shown and described herein). Test holes 2118 may optionally be present in lamp holders 2106 to receive continuity test probes.

FIG. 22 also shows lamp center lines L2, which correspond to lamps that may be installed in lamp support 2100. Distance C2 between adjacent lines L2 may be adjusted by sliding lamp holders 2152 and 2154. By adjusting C2 during a manufacturing or assembly process, lamp support 2100 may be used for different luminaires having different center-to-center lamp distances.

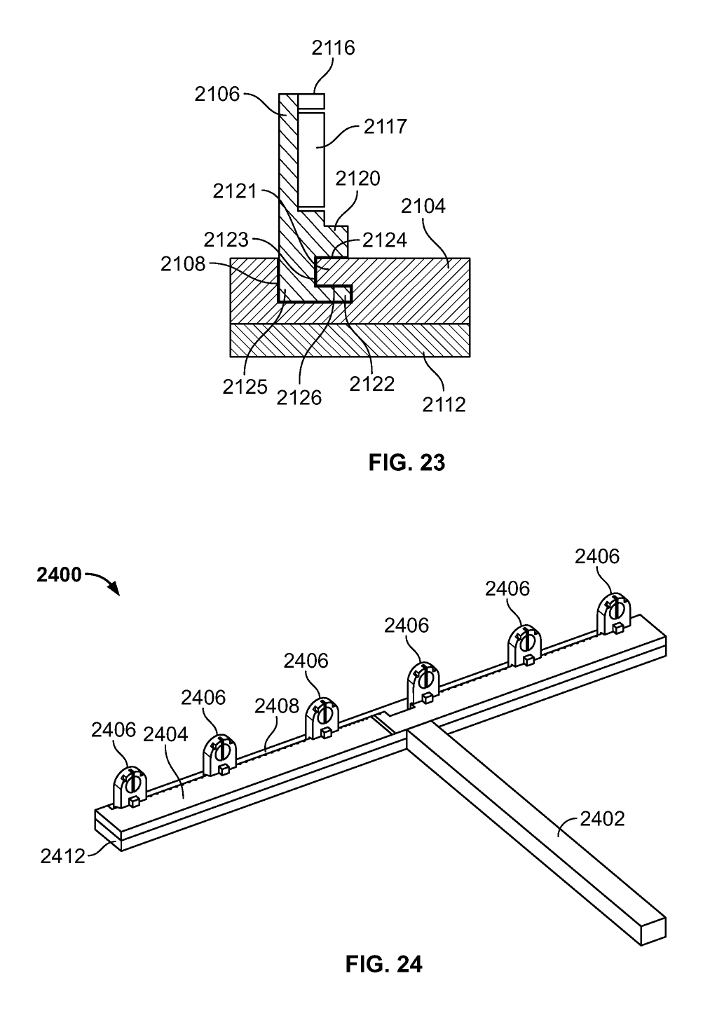

FIG. 23 shows additional detail of the lamp holders 2106 and their mechanical and electrical interface with rigid power distribution unit 2104. Slots 2116 may open up to a cavity (not shown) for receiving the end of a lamp. Contact pin guide 2117 may guide pins at the end of the lamp during installation of the lamp in lamp holder 2106. Lamp holder 2106 may include groove 2123, which may be defined at least in part by bosses 2120 and 2122. Groove 2123 may receive tongue 2121 of rigid power distribution unit 2104. Knee 2125 at the base of lamp holder 2106 may occupy groove 2108. Any suitable adjacent surfaces between lamp holder 2106 and rigid power distribution unit 2104 may be used for transferring electrical power between the two. For example, interfacial surfaces 2124 and 2126 may include electrical contacts for transferring the power. In general, positive and negative contact will be present on lamp holder 2106 and rigid power distribution unit 2104. In some embodiments, the positive and negative contacts may be in opposite sides of a structure, such as tongue 2121. In some embodiments, the positive and negative contacts may be separated from each other, but on the same interfacial surface.

FIG. 24 shows illustrative lamp support 2400. Lamp support 2400 includes ballast 2402 in a perpendicular orientation with respect to rigid power distribution unit 2404 and plate 2412. Lamp holders 2406 are slidably mounted in track 2408. It will be appreciated that the ballasts shown and described herein may be mounted in any suitable orientation with respect to a corresponding rigid power distribution unit.

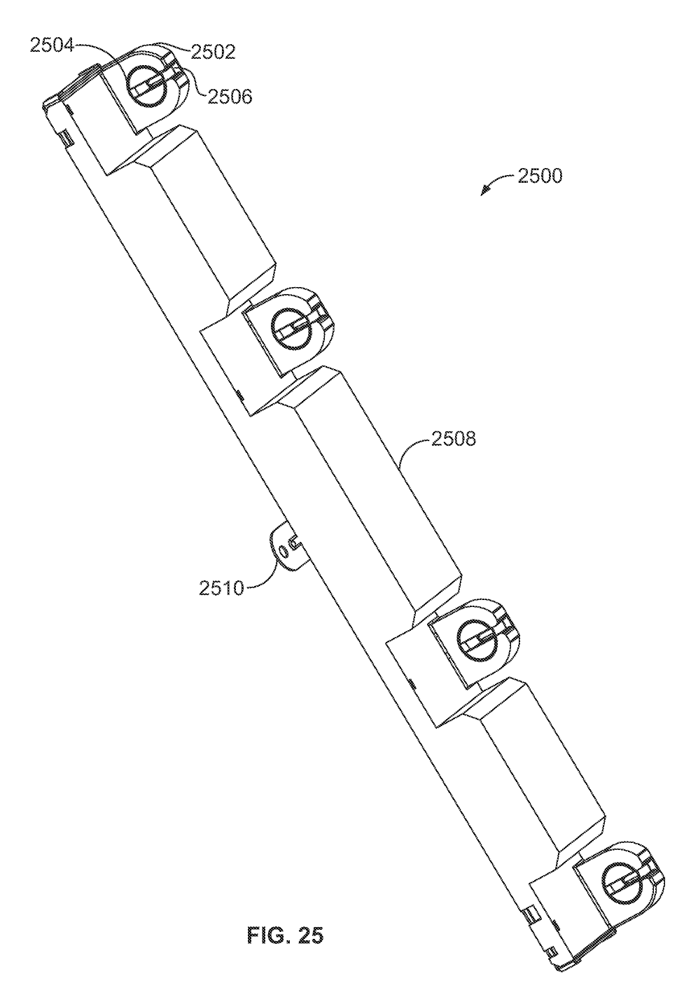

FIG. 25 shows illustrative ballast module 2500. Illustrative ballast module 2500 may include lamp holders 2502. Lamp holders 2502 may have one or more of the features shown or described herein in connection with lamp holder 200. Lamp holders 2502 may include lamp pin guide 2504. Lamp pin guide 2504 may alternatively be referred to as a rotor. Lamp pin guide 2504 may be configured to facilitate the rotation of paired contact pins from a fluorescent lamp. Lamp holders 2502 may additionally include pin slot 2506. Pin slot 2506 may be configured to receive paired contact pins from a fluorescent lamp.

Illustrative ballast module 2500 may include ballast cover 2508. Ballast cover 2508 may at least partially enclose the circuitry of a T5, T8 or T12 ballast. Illustrative ballast module 2500 may include fastening feature 2510. Fastening feature 2510 may be used to attach ballast module 2500 to a fixture housing.

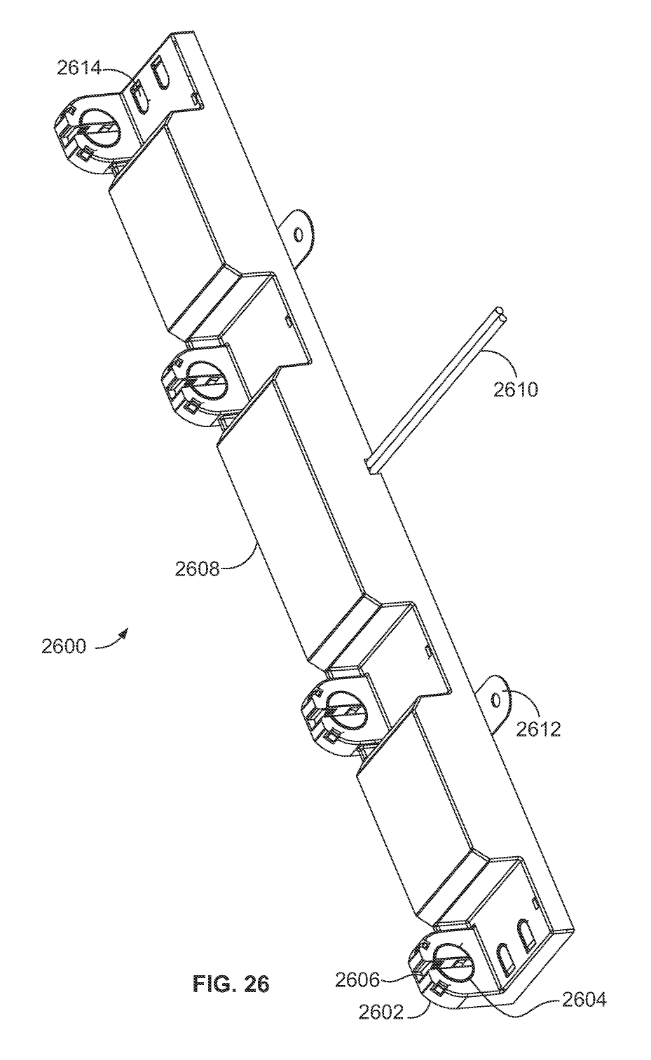

FIG. 26 shows illustrative ballast module 2600. Illustrative ballast module 2600 may include lamp holders 2602, lamp pin guide 2604, pin slot 2606, ballast cover 2608 and fastening feature 2612. Illustrative ballast module 2600 may include conductors 2610. Conductors 2610 may be wires. Conductors 2610 may draw power from a 120-V power source or any other suitable power source. The power drawn by conductors 2610 may be used to power ballast circuitry enclosed in ballast cover 2608. Illustrative ballast module 2600 may also include socket 2614.

FIG. 27 shows a frontal view of ballast module 2600.

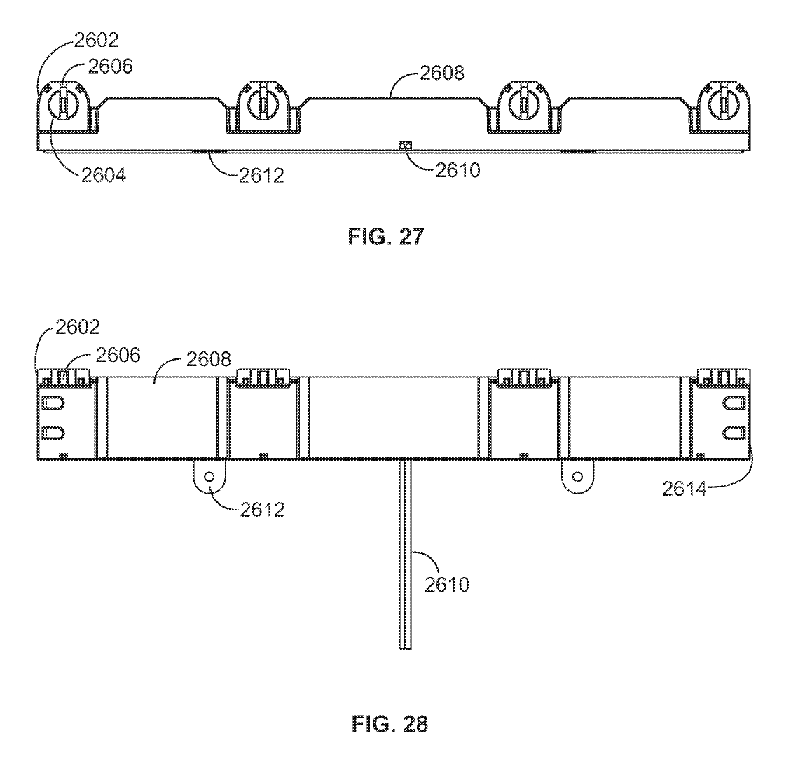

FIG. 28 shows a plan view of ballast module 2600.

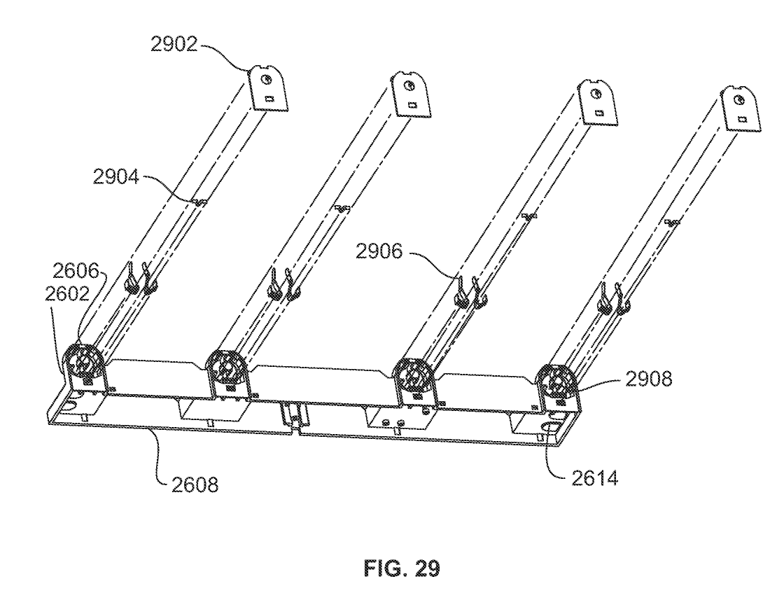

FIG. 29 shows a partially exploded perspective view of ballast module 2600. Ballast module 2600 may include cover 2902. Cover 2902 may be used to cover components present in lamp holders 2602. Ballast module 2600 may additionally include shunt contact 2904, pin contact 2906, and rotor 2908. These components may enable a fluorescent lamp to be supported and/or powered by lamp holders 2602.

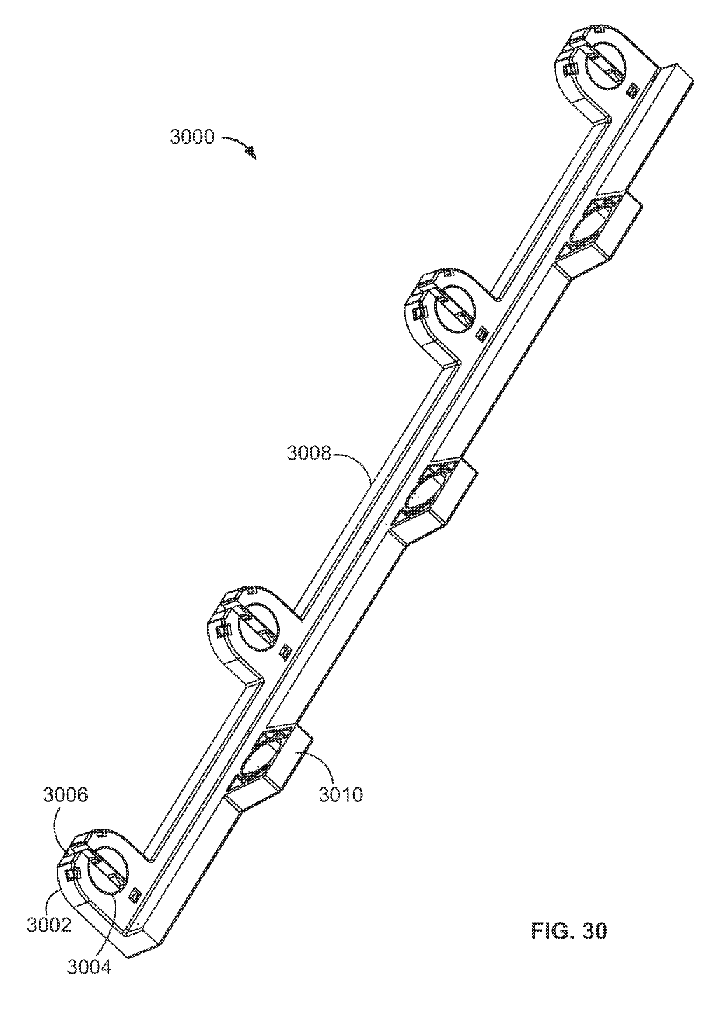

FIG. 30 shows illustrative lamp holder module 3000. Lamp holder module 3000 may include lamp holders 3002. Lamp holders 3002 may have one or more of the features shown or described herein in connection with lamp holder 200. Lamp holders 3002 may include lamp pin guide 3004. Lamp pin guide 3004 may alternatively be referred to as a rotor. Lamp pin guide 3004 may be configured to facilitate the rotation of paired contact pins from a fluorescent lamp. Lamp holders 3002 may additionally include pin slot 3006. Pin slot 3006 may be configured to receive paired contact pins from a fluorescent lamp.

Lamp holder module 3000 may include enclosure 3008. Enclosure 3008 may enclose a portion of the components included in lamp holder module 3000. Alternately, enclosure 3008 may enclose all of the components included in lamp holder module 3000. Lamp holder module 3000 may further include fastening feature 3010. Fastening feature 3010 may facilitate the attachment of lamp holder module 3000 to a lamp fixture housing.

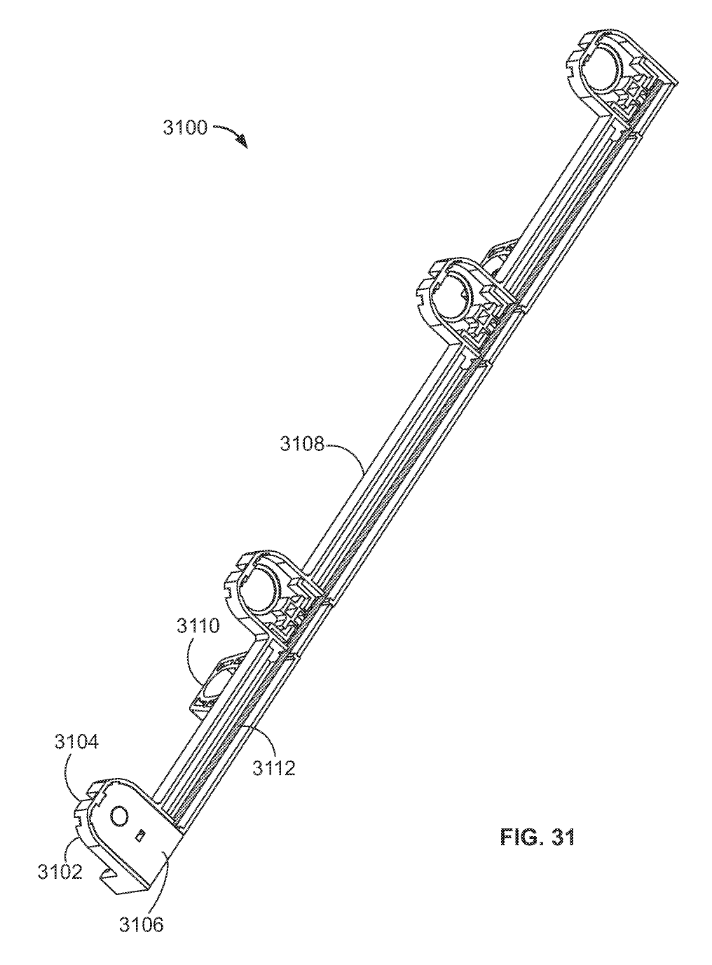

FIG. 31 shows a portion of illustrative lamp holder module 3100. Lamp holder module 3100 may include lamp holders 3102, lamp pin guide 3104, pin slot 3106, enclosure 3108 and fastening feature 3110. Lamp holder module 3100 may include conductor 3112. Conductor 3112 may be used to power a fluorescent lamp supported by lamp holder 3102.

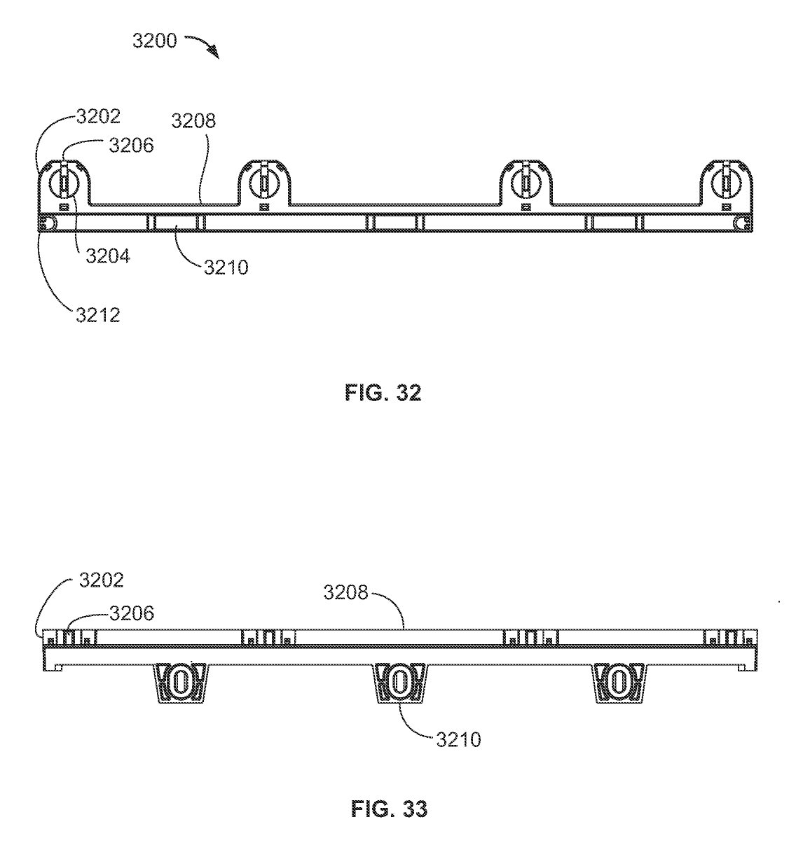

FIG. 32 shows a frontal view of illustrative lamp holder module 3200. Lamp holder module 3200 may include lamp holders 3202, lamp pin guide 3204, pin slot 3206, enclosure 3208 and fastening feature 3210. Lamp holder module 3200 may additionally include conductors 3212.

FIG. 33 shows a plan view of lamp holder module 3200.

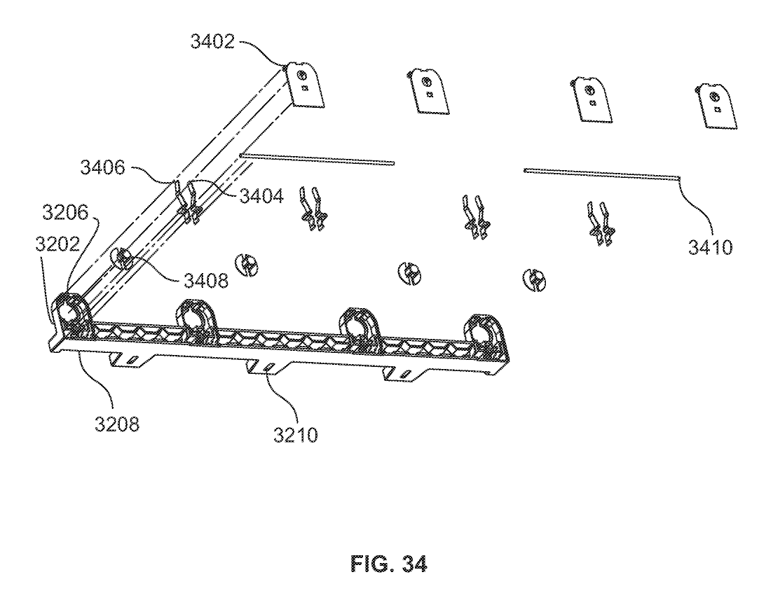

FIG. 34 shows an exploded perspective view of lamp holder module 3200. Lamp holder module 3200 may include cover 3402. Cover 3402 may enclose components present in lamp holders 3202. Lamp holder module 3200 may additionally include right contact 3404, left contact 3406, rotor 3408 and conductor 3410. These components may enable a fluorescent lamp to be supported and/or powered by lamp holder 3202.

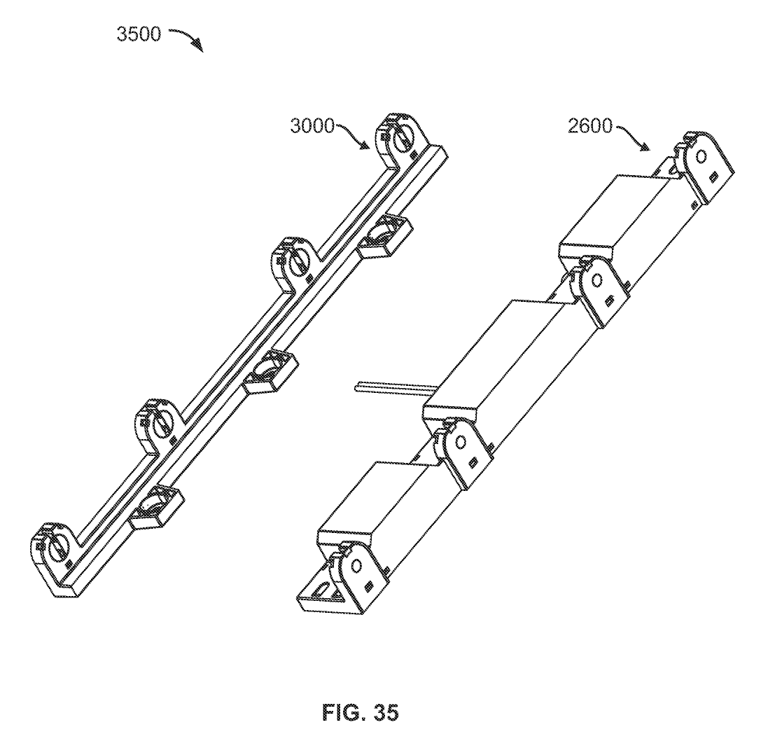

FIG. 35 shows illustrative arrangement 3500 that includes ballast module 2600 and lamp holder module 3000. Arrangement 3500 may represent the relative positions of ballast module 2600 and lamp holder module 3000 when fixed to a housing.

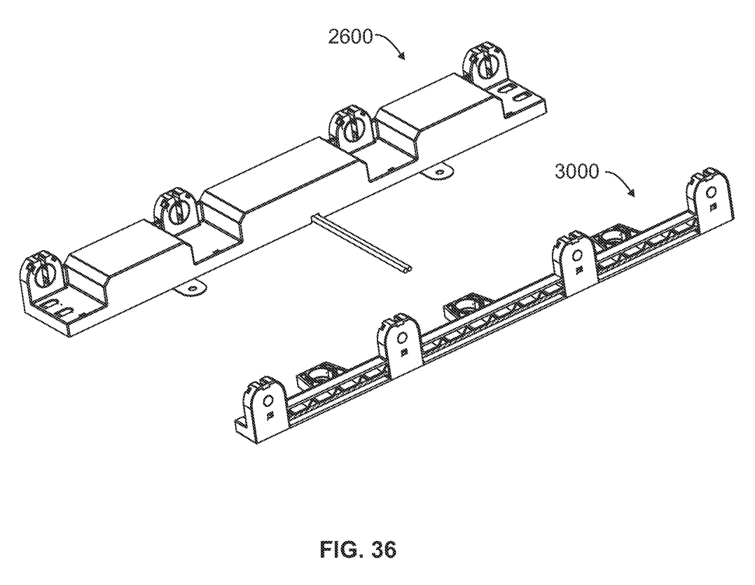

FIG. 36 shows a perspective view of arrangement 3500.

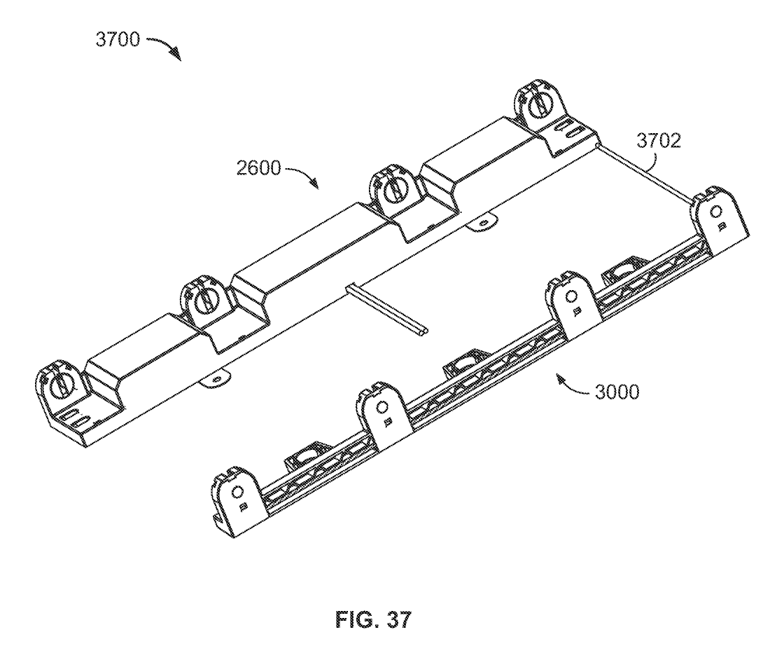

FIG. 37 shows illustrative arrangement 3700 that includes ballast module 2600 and lamp holder module 3000. Illustrative arrangement 3700 includes conductor 3702. Conductor 3702 may be in electrical contact with ballast module 2600 and lamp holder module 3000. Arrangement 3700 may represent the relative positions of ballast module 2600 and lamp holder module 3000 when fixed to a housing.

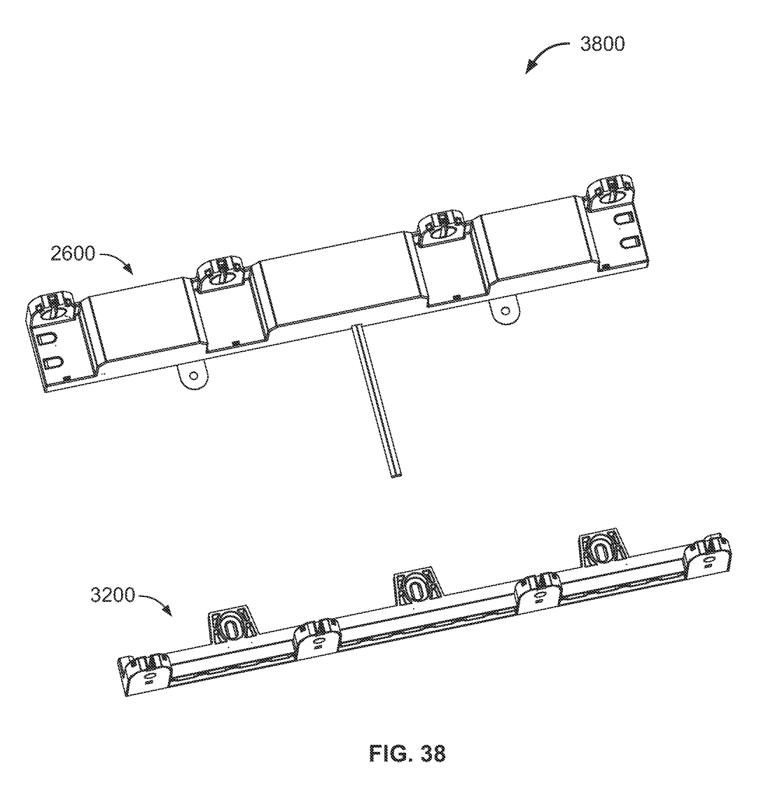

FIG. 38 shows illustrative arrangement 3800 that includes ballast module 2600 and lamp holder module 3200. Arrangement 3800 may represent the relative positions of ballast module 2600 and lamp holder module 3200 when fixed to a housing.

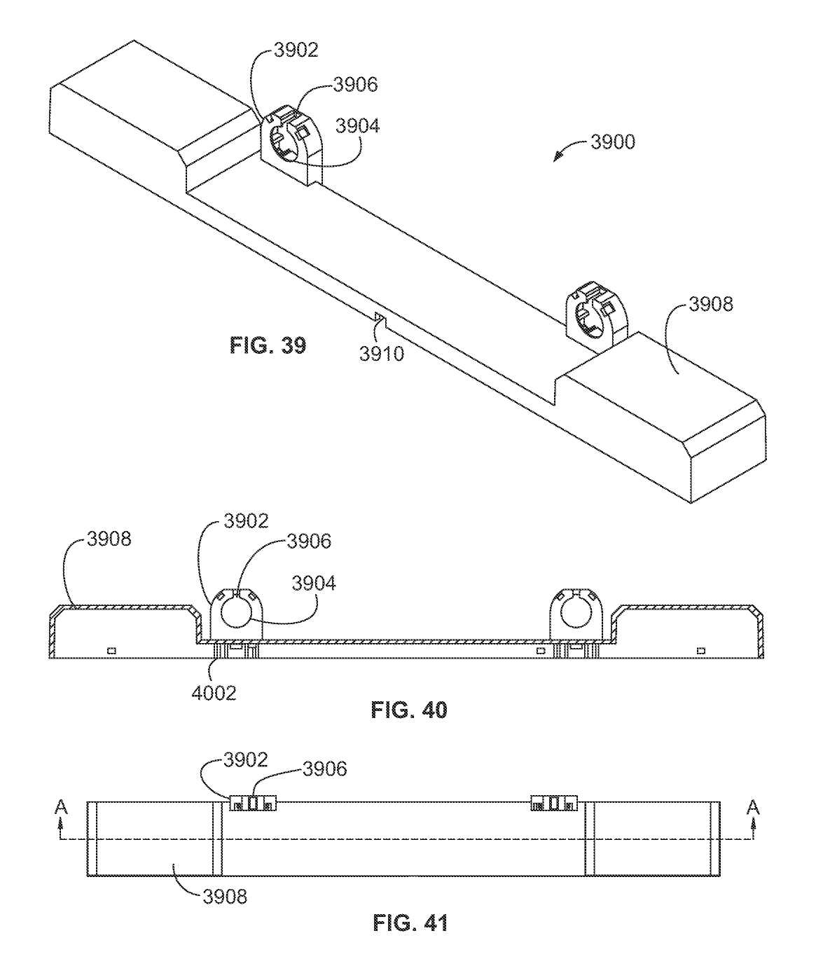

FIG. 39 shows illustrative retrofit ballast module 3900. Retrofit ballast module 3900 may be configured replace one or more functionalities of a previously installed ballast module. Retrofit ballast module 3900 may include lamp holders 3902, lamp pin guide 3904 and pin slot 3906. Retrofit ballast module 3900 may additionally include ballast cover 3908. Retrofit ballast module 3900 may also include opening 3910. Power lines may pass through opening 3910 and connect to a suitable voltage source.

FIG. 40 shows a partial cross-sectional view of retrofit ballast module 3900. Retrofit ballast module 3900 may include connector 4002. Connector 4002 may secure lamp holder 3902 to the base of retrofit ballast module 3900.

FIG. 41 shows a plan view of retrofit ballast module 3900.

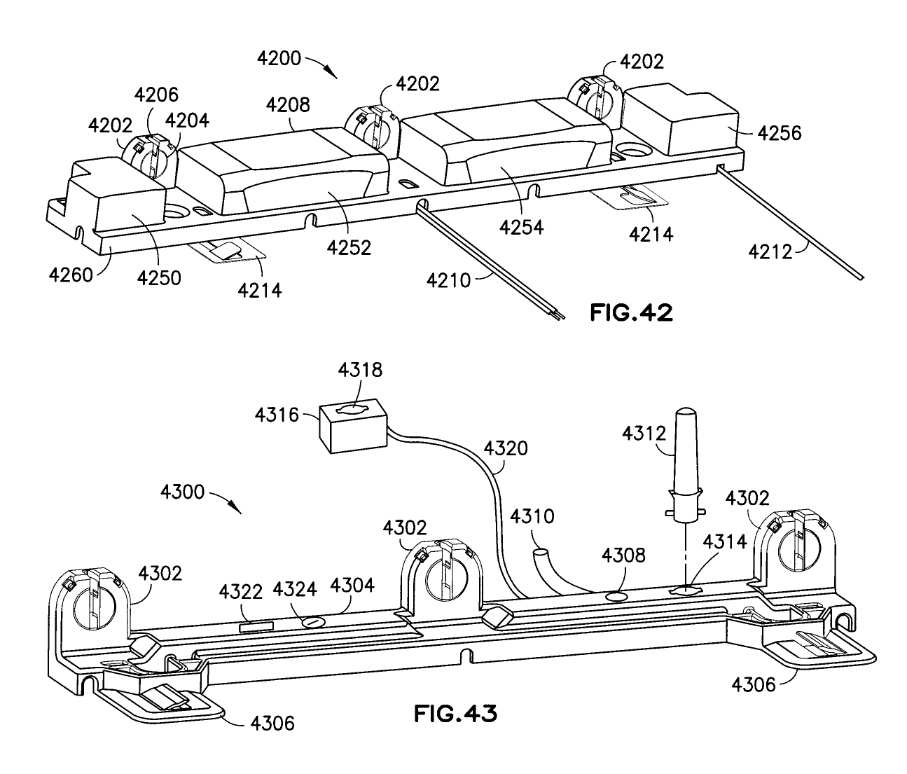

FIG. 42 shows a perspective view of a ballast module or first end section 4200 of a light fixture, wherein the light fixture may be a self-contained, automatically configured luminary device. The first end section 4200 may be a modular unit that includes ballast circuitry of the light fixture. In this embodiment, the first end section 4200 includes three lamp holders 4202, where each lamp holder 4202 includes a lamp pin guide 4204 and a pin slot 4206. As is well known in the art, the lamp pin guide 4204 and pin slot 4206 of each lamp holder 4202 are configured to allow one end of a lamp (e.g., a fluorescent lamp, LED lamp, or other type of elongated lamp having pins at its ends) to be inserted in the lamp holder 4202 and held in place. Pins of the lamp are configured to make electrical contact with conductors of the lamp holders 4202 for receiving power for illuminating the lamp. It should be well understood that the present disclosure is not limited to three lamp holders and may include one, two, four, or more lamp holders.

The first end section 4200 may further include a ballast cover 4208, which may be configured as a housing having an interior space. The ballast cover 4208 is configured to house a ballast and other electronics as described below. In some embodiments, the ballast cover 4208 may include one or more sections located between the lamp sockets 4202 and which extend beyond a base element 4260. As specifically shown in FIG. 42, the ballast cover 4208 may include four sections 4250, 4252, 4254, and 4256 that extend beyond the base element 4260. The present disclosure is not limited to four sections and may include any number of sections. The ballast, ballast circuitry, and/or other electronics may be located in any one or more of the sections 4250, 4252, 4254, and 4256, or in other embodiments may be located in a second end section 4300 (described below with respect to FIG. 43). Conductors, wires, connectors, or other electronics may be used to electrically connect the four sections 4250, 4252, 4254, 4256 via the base element 4260.

The ballast cover 4208 may further enclose processing circuitry (not shown) for processing the signals indicative of sensed conditions detected by one or more sensors as described herein. In some embodiments, the processing circuit may be part of a ballast circuit that includes at least the ballast. The processing circuit may be further configured to control the illumination of the three lamps based on the sensed environmental conditions.

In addition, one or more conductors 4210 may be configured to extend from the first end section 4200 to the second end section 4300 of a light fixture. The conductors 4210 may include a single conductor or a multi-conductor cable, and may include one or more wires or conductors for supplying power to the first end section 4200 and/or the second end section 4300. In other embodiments, the conductor 4210 may be configured for receiving power from a power source, e.g., 120 VAC.

A control conductor 4212 may also extend between the first end section 4200 and the second end section 4300. The control conductor 4212 may include a single conductor or a multi-conductor cable, and may include one or more wires or conductors for transmitting control signals between the two end sections. The control conductor 4212 may communicate analog or digital signals. The second end section 4300 may be configured, according to various embodiments of the present disclosure, to detect environmental conditions and communicate the sensed conditions to the first end section 4200. It should be understood that the intelligence for detecting environmental conditions and controlling lamp illumination and other circuitry may be located in the first end section 4200, in the second end section 4300, or in any combination of the first and second end sections 4200 and 4300. Therefore, depending on the particular arrangement of the circuitry within the two end sections 4200 and 4300, the control conductor 4212 may be used to communicate signals as needed from one end section to the other, and vice versa.

The first end section 4200 may further include one or more clips 4214, which are configured to support a reflector. The clips 4214 may be snapped onto the ballast cover 4208 or may be integrally molded with the ballast cover 4208.

FIG. 43 shows a perspective view of the lamp holder module or second end section 4300 of a light fixture. The second end section 4300 may be a modular unit and may be combined with the first end section 4200 shown in FIG. 42 to create two ends of a light fixture. The second end section 4300 includes three lamp holders 4302, which may be similar in design to and aligned with the lamp holders 4202 shown in FIG. 42. However, according to some embodiments, the lamp holders 4302 may be configured without circuitry for providing power to the lamps. Instead, the lamp holders 4302 may be configured for simply supporting the second ends of the lamps. It should be well understood that the present disclosure is not limited to three lamp holders 4302 and may include one, two, four, or more lamp holders.

The second end section 4300 may also include a cover 4304, which may be configured as a housing having an interior space. The cover 4304 may be configured to house or support one or more environmental sensors, or other electronics, and associated circuitry as described herein. In some embodiments, the cover 4304 may include one or more sections (as previously described) located between the lamp sockets 4302 and which extend beyond a base element. The second end section 4300 may also include one or more clips 4306. The clips 4306 may be snapped onto the housing 4304 or integrally molded with the housing 4304. The clips 4214 (FIG. 42) and the clips 4306 (FIG. 43) may be used together to support a reflector. Although two clips are illustrated on each of the end sections 4200 and 4300, it should be understood that other embodiments may include other numbers of clips for adequately supporting the reflector. In this respect, the reflector may be clipped on the light fixture using clips 4214 and 4306 for reflecting light in predetermined directions.

According to some embodiments, the second end section 4300 may also include one or more environmental sensors. In use, the sensors may be configured to detect various environmental conditions. For example, the various types of environmental sensors may include occupancy sensors, ambient-light detectors (e.g., photocell or photo-sensor), humidity sensors, temperature sensors, or any other type of sensor now or hereafter known. In use, for example, the occupancy sensors may be configured to detect motion (e.g., motion detector), detect external sounds, or detect other conditions that may indicate that one or more people are near the light fixture (e.g., in the same room). Occupancy signals may be sent to the first end section 4200, where the processing circuitry is housed within the ballast cover 4208 to determine whether or not people are present. Alternatively, the electronic control circuitry may be located within the housing of the second end section 4300. When configured as an ambient light detector, the sensor is configured to detect the amount of natural light illuminating an area independent of the amount of illumination produced by the lamps themselves. In other words, the ambient light detector is configured to detect at least some natural light. In this respect, the sensor may be used for daylight calibration purposes, to adjust the power to the lamps as needed according to the amount of natural light that already illuminates portions of a room or space. If a room already receives enough natural light, the lamps may be turned off or dimmed to reduce energy costs. Therefore, the sensor may be positioned such that they are capable of detecting natural light without substantial interference from the illumination of the lamps. As such, the sensor may be positioned such that it is not exposed directly to the light from the light fixture itself. For example, the sensor in this case can be tethered to an outside surface of a bracket of a lamp holder.

The environmental sensors may be positioned on a portion of the housing or ballast cover such that it is exposed to the environment. Alternatively, the sensors may be mounted on or near where the light fixture is mounted. In some embodiments, the sensors may be mounted on a dimple or bracket of a lamp holder. Additional embodiments include an outboard sensor module, wherein the sensor may be attached to the edge of the light fixture or installed or attached to an adjacent or nearby ceiling tile. The sensors may be supported by a structure, such as a gooseneck support, that extends outside of the housing of the light fixture. More specifically, the environmental sensor 4308 may be completely incorporated into the housing 4304. The sensor 4308 may be mounted above, at, or below a surface of the housing 4304. Alternatively, the sensor may be a bayonet type sensor 4312 that includes a bayonet connection for inserting into an appropriate slot or receptor 4314 formed in the housing 4304. The bayonet-type sensor 4312 may be configured to extend outwardly by a certain distance from the housing 4304 to be sufficiently clear of the lamps installed in the lamp holders 4302. It should be noted that the sensor may include other forms of connections aside from a bayonet style coupling including, but not limited to, screw threading, snap-fit, etc. Alternatively, the sensor may be operatively coupled to and/or supported by the second end section 4300. For example, the sensor may be attached to the housing 4304. That is, for example, the sensor may be a gooseneck sensor 4310, which is attached to the back region of the housing 4304. In this manner, the position and orientation of the sensor 4310 may be adjusted as needed to position the sensor where it will not be adversely affected by the light of any lamps controlled by the light fixture. In use, the second end section 4300 may include a sensor housing 4316 having a receptacle 4318 configured to receive a sensor 4312. According to the arrangement with the separate sensor housing 4316, a conductor 4320 is connected at one end to the sensor housing 4316 and may be connected at its other end to control circuitry within the housing 4304. In this respect, the sensor housing 4316 may be positioned in various locations. For example, the sensor housing 4316 may be clipped onto an outside portion of the housing 4304, ballast cover 4208 (FIG. 42), enclosure 5102 (FIG. 51), or other component of the light fixtures disclosed herein. Also, according to some embodiments, the sensor housing 4316 may be installed in, on, or through a ceiling tile adjacent to or near the light fixtures.

It should be understood that the first end section 4200 and/or second end section 4300 may be configured to support any number and style of sensors 4308.

Also, the housing 4304 may include electronic control circuitry (not shown) associated with the sensors for processing the signals related to the detected environmental conditions. The associated electronic control circuitry may also be configured to send signals via the control conductor 4212 (FIG. 42) or wirelessly from the second end section 4300 to the first end section 4200, or vice versa.

By configuring the first end section 4200 and second end section 4300 as described above, a self-contained, automatically configured luminary device is provided. The electronic control circuitry may be preconfigured to operate with at least one predetermined environmental sensor. Alternatively, the electronic control circuitry may auto-detect which type of sensor has been coupled to the electronic control circuitry and then configure itself to operate with the detected sensor. The electronic control circuitry may send control signals to the ballast based on sensed conditions. It is to be appreciated that the electronic control circuitry may be implemented in various forms of hardware, software, firmware, special purpose processors, or a combination thereof. Additionally, based on the type of sensor that is employed, the electronic control circuitry may be configured to automatically calibrate the components of the light fixture based on sensed conditions. An exemplary automatic calibration method is disclosed in commonly-owned U.S. Pat. No. 7,608,807, the contents of which are hereby incorporated by reference.

In this manner, a self-contained, automatically configured luminary device may be assembled by providing a light fixture housing having a first end section and a second end section. The first end section 4200 being mounted to the first end of a lighting fixture and the second end section 4300 being mounted to the second end of the lighting fixture. At least one lamp is inserted between the first and second end sections. Upon powering up the first and second end sections 4200, 4300, the electronic control circuitry configures its operation based on at least one predetermined environmental sensor and automatically calibrates the luminary device.

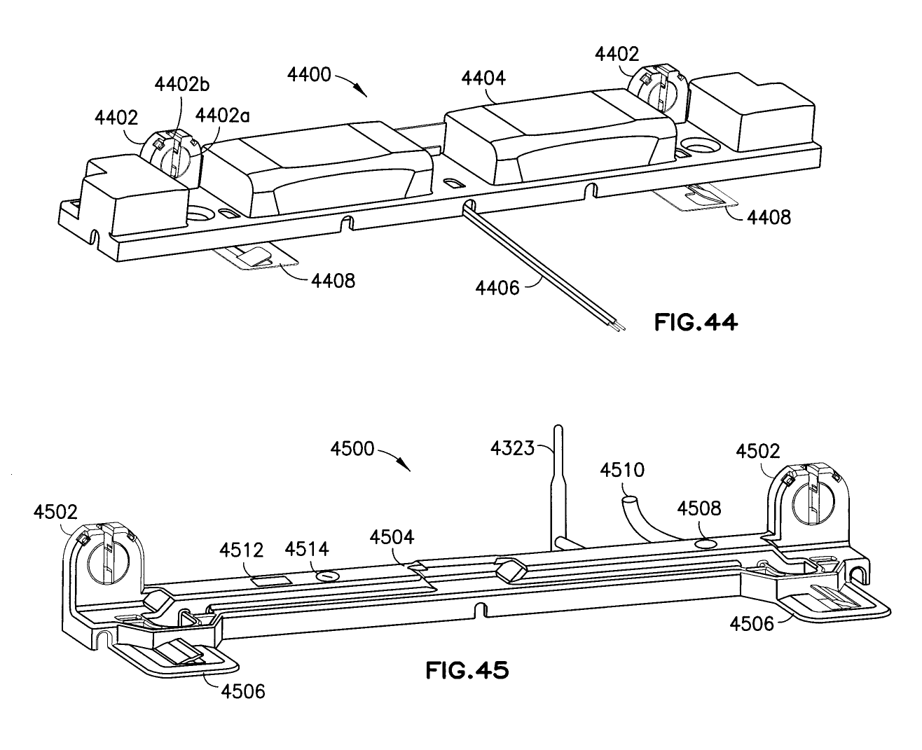

FIGS. 44 and 45 illustrate perspective views of a first end section 4400 and a second end section 4500 of an alternative embodiment of a light fixture that may be a self-contained, automatically configured luminary device. The embodiments shown in FIGS. 44 and 45 are substantially similar to the embodiments shown in FIGS. 42 and 43 but include two lamp holders on each of the first and section end sections 4400 and 4500 respectively. That is, in this embodiment, the first end section 4400 includes two lamp holders 4402, where each lamp holder 4402 includes at least a lamp pin guide 4402a and a pin slot 4402b configured to allow one end of a lamp (e.g., a fluorescent lamp, LED lamp, or other type of elongated lamp having pins at the ends) to be inserted in the lamp holder 4402 and held in place. As described above in relation to FIG. 42, the first end section 4400 may further include a ballast cover 4404, which may be configured as a housing having an interior space. In addition, one or more conductors 4406 may be configured to extend from the first end section 4400 to a second end section of the light fixture. The first end section 4400 may further include one or more clips 4408, which are configured to support a reflector. The clips 4408 may be snapped onto the ballast cover 4404 or integrally molded with the ballast cover 4404.

The second end section 4500 may be a modular unit and may be combined with the first end section 4400 shown in FIG. 44 to create two ends of a light fixture. The second end section 4500 includes two lamp holders 4502, which may be similar in design to and aligned with the lamp holders 4402 shown in FIG. 44. However, according to some embodiments, the lamp holders 4502 may be configured without circuitry for providing power to the lamps. Instead, the lamp holders 4502 may be configured for simply supporting the second ends of the lamps. The second end section 4500 may also include a housing 4504 and one or more clips 4506, which may be snapped onto housing 4504 or integrally molded with housing 4504. The clips 4408 (FIG. 44) and the clips 4506 (FIG. 45) may be used together to support a reflector. Although two clips are illustrated on each of the end sections, it should be understood that other embodiments may include other numbers of clips for adequately supporting the reflector. In this respect, the reflector may be clipped on the light fixture using clips for reflecting light in predetermined directions.

As previously described above, the housing 4504 may be configured, according to some embodiments, to support sensors for sensing environmental conditions. For example, the housing 4504 may include at least one environment sensor. For example, as previously described above, the housing may include at least one environmental sensor 4508 incorporated into the housing 4504 and/or at least one sensor 4510 operatively coupled to the housing 4504. The sensors 4508, 4510 and associated circuitry may be configured to send signals via a control conductor or sent wirelessly from the second end section 4500 to the first end section 4400.

According to various implementations, the above-mentioned environmental sensors may be incorporated in or on various housings on the first end section and/or the second end section of the light fixture. For example, these sensors may be included in embodiments with respect to the light fixture having first end section 4200 (FIG. 42) and second end section 4300 (FIG. 43), the light fixture having first end section 4400 (FIG. 44) and second end section 4500 (FIG. 45), or included in other embodiments having other various combinations of components. The environmental sensors may be supported by the housing 4304, the housing 4504, or by other housings or ballast covers. When the environmental sensors are positioned in or supported by the second ends of the light fixtures (e.g., second end section 4300 or second end section 4500), the signals are preferably sent to the respective first ends (e.g., first end section 4200 or first end section 4400). For example, the signals may be sent via control conductor 4212. In other embodiments, as will be described in greater detail below, signals may be sent wirelessly using antennas on the end sections. Antennas may be attached to the ballast cover 4404 and housing 4504 for enabling wireless communication between the two end sections. Also, the processing circuitry within the ballast cover 4208 or 4404 may be configured to control the illumination of the lamps depending on various aspects of the sensed condition(s).

In other embodiments, the lamp holder module or second end section 4300, 4500 of the light fixture may include a receiver 4322, 4512. Alternatively, the receivers 4322, 4512 may be incorporated into the first end sections 4200, 4400. The receiver 4322, 4512 is preferably configured to receive (e.g., via an antenna 4323 protruding from the housing) wireless control signals that are sent to the ballast to control one or more of the lamps. For example, the receiver 4322, 4512 may use a wireless protocol known as Levnet, which is provided by Leviton Manufacturing Company, Inc. of Melville, N.Y. The control signals may be received, for example, from an occupancy sensor, a photocell, a wall switch or a group of wall switches designed to operate in conjunction with the ballast. Also, a single wall switch may be configured to operate several light fixtures. In one embodiment, a single wall switch may be associated to one or more light fixtures via an over-the-air (OTA) pairing process.

In another embodiment, the lamp holder module or second end section 4300, 4500 of a light fixture may include an addressing switch 4314 or 4514 to individually address each light fixture. The addressing switch 4314 or 4514 will enable the corresponding ballast or light fixture to be individually controlled on a network. The addressing switch 4314 or 4514 may be any suitable type of programmable switch, such as DIP switches, rotary switches, or other switches. The addressing switch may be disposed on the housing 4304 to be externally accessible obviating the need to open the housing 4303 to address the light fixture. In other embodiments, the address of an individual light fixture may be programmed via a software program instead of via a physical addressing switch such as switch 4314 or 4514.

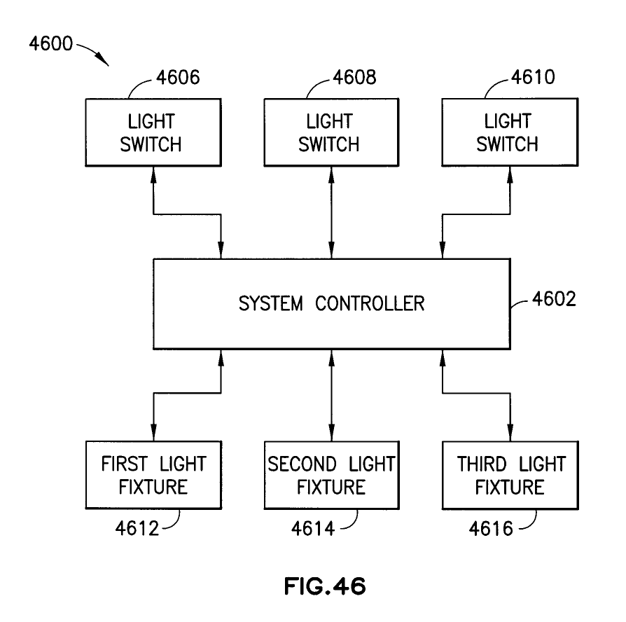

FIG. 46 is a block diagram illustrating a network 4600 of light fixtures in accordance with various implementations of the present disclosure. The network 4600, as shown, includes a system controller 4602, at least one light switch 4606, 4608, and 4610 (e.g., a wall switch) and at least one light fixture 4612, 4614, 4616. Although three switches are illustrated in this embodiment, it should be noted that the network 4600 may include any number of switches depending on the number of light fixtures provided. The system controller 4602 is configured to provide individual control for each of the light fixtures regardless of how any single light fixture is wired. It is to be appreciated that the network 4600 may operate under various known communication protocols, for example, the Digital Addressable Lighting Interface (DALI) protocol, among others, or using software such as SectorNET provided by Leviton Manufacturing Company, Inc. of Melville, N.Y., or other software.

In one embodiment, each switch is programmed to address a single light fixture. Therefore, when control signals are received to turn on a first light fixture (identified by a particular address on the switch), the controller 4602 is configured to turn on that first light fixture. In other embodiments, the system controller 4602 may be configured to match any single switch 4606, 4608, 4610 to any single light fixture 4612, 4614, 4616 or to have any single switch control any group of light fixtures. Also, additional instructions may be received in the control signals for controlling the other lamps, depending on a particular user need. For example, instructions may be received to dim the first and second light fixtures to 50% power and to turn the third light fixture off, or instructions may be received to illuminate the first light fixture at 70% power while illuminating the second and third light fixtures at full power. These and other levels of precision for each light fixture may be controlled using the controller 4600 or 4602.

The light fixture, according to some embodiments, may be configured to respond to demand response (DR) signals or automated demand response (auto-DR) signals. The light fixture may operate according to DR and auto-DR specifications and is configured to adhere to various standards associated with the American Society of Heating, Refrigerating and Air Conditioning Engineers (ASHRAE), such as the building automation and control network (BACnet), digital addressable lighting interface (DALI), among others. For example, a power utility company may transmit auto-DR signals for the purpose of informing its customers when energy demand is high, when a black-out may occur, or other circumstances when power provided to the lamps should be cut off or minimized. In these situations, the receiver 4312 is configured to receive the auto-DR signals and inform the electronic control circuit of any instructions from the power utility company. In response, the electronic control circuit can turn off or dim the lamps, as needed.

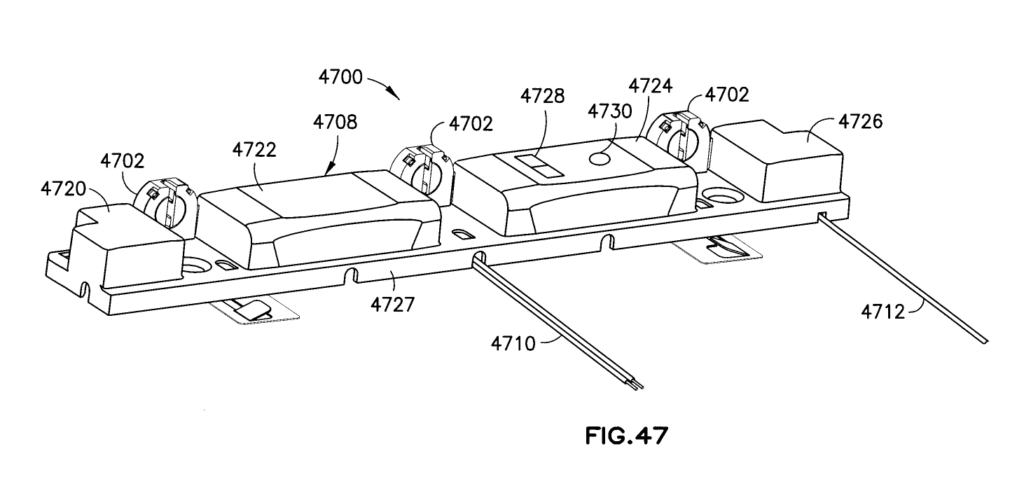

According to some embodiments, the modular light fixture may further comprise an emergency backup power supply contained within the first or second end. Referring to FIG. 47, a perspective view of an emergency backup power supply module or end section 4700 of a light fixture configured for containing the emergency backup power supply and associated circuitry is illustrated. In this embodiment, the end section 4700 includes three lamp holders 4702, as described above. It is to be appreciated that fewer or more than three lamp holders may be provided in other embodiments. The end section 4700 further includes a cover 4708, which may be configured as a housing having at least one interior space. The cover 4708 is configured to house at least one rechargeable battery and other electronics as described below. In some embodiments, the cover 4708 may include four sections, e.g., sections 4720, 4722, 4724 and 4726, that extend beyond a base element 4727. Conductors, wires, connectors, or other electronics may be used to electrically connect the four sections via the base element. In addition, conductors 4710 are configured to extend from the end section 4700 to a power source for recharging batteries contained in the housing. Additionally, a control conductor 4712 may also extend between the end section 4700 to a ballast module. The control conductor 4712 may include a single conductor or a multi-conductor cable, and may include one or more wires or conductors for transmitting control signals and/or power between the two end sections. It should be understood that the ballast may be included in the same end section or the opposite end section from where the power supply module is contained. It is to be appreciated that when the power supply module is disposed in the opposite end section of the ballast the first and second end sections will be electrically coupled so the power supply module powers the ballast.

The emergency backup power supply module 4700 may comprise at least one rechargeable battery, a charging circuit configured to charge the at least one rechargeable battery, and a power outage detecting circuit configured to detect the occurrence of a power outage. In certain embodiments, sections 4720, 4722, 4724 4726 will house the at least one rechargeable battery. It is to be appreciated that the number and size of the rechargeable batteries will depend on the number of lamps in the light fixture, the required number of amp-hours, among other factors. Conductors 4710 are coupled to each of the at least one battery and are configured to be coupled to a power source for recharging the at least one battery contained in the housing 4702.

Sections 4720, 4722, 4724, 4726 may further house the charge circuit and/or the power outage detecting circuit. When the power outage detecting circuit detects a power outage, the at least one rechargeable battery may be configured to provide power to the ballast and electronic control circuit via control conductor 4712. The charging circuit charges the at least one rechargeable battery from power that is also supplied to the ballast and electronic control circuit via conductors 4710. The charging circuit may alternatively charge the at least one rechargeable battery from power supplied by a remote circuit.

In other embodiments, the emergency backup power supply module or end section 4700 may also include an accessible test switch 4728 integrated into the housing for testing the back-up power and at least one LED 4730 to show whether a back-up power test has passed or failed. A remote test switch may also be used for testing the back-up power.

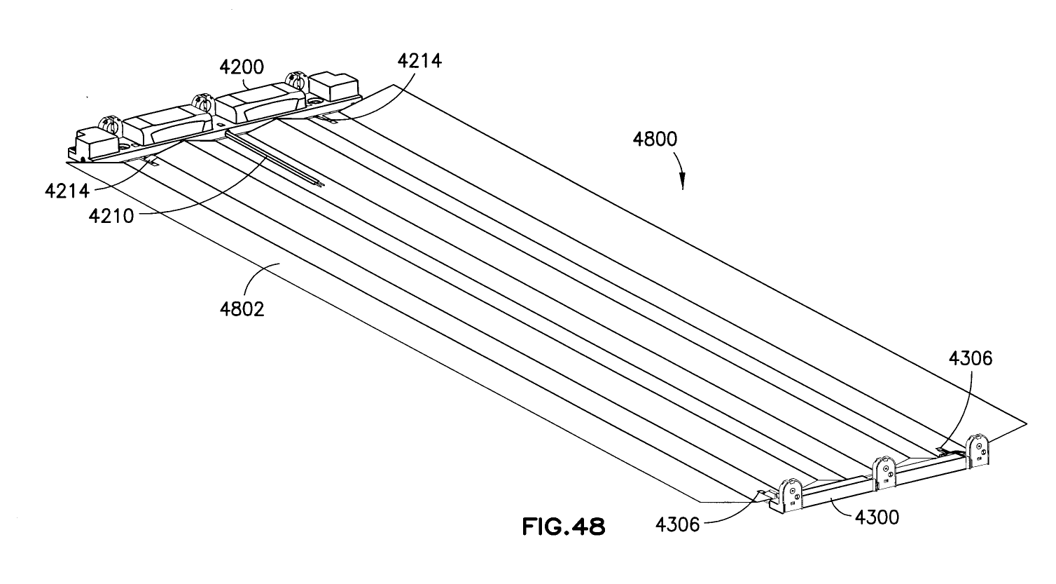

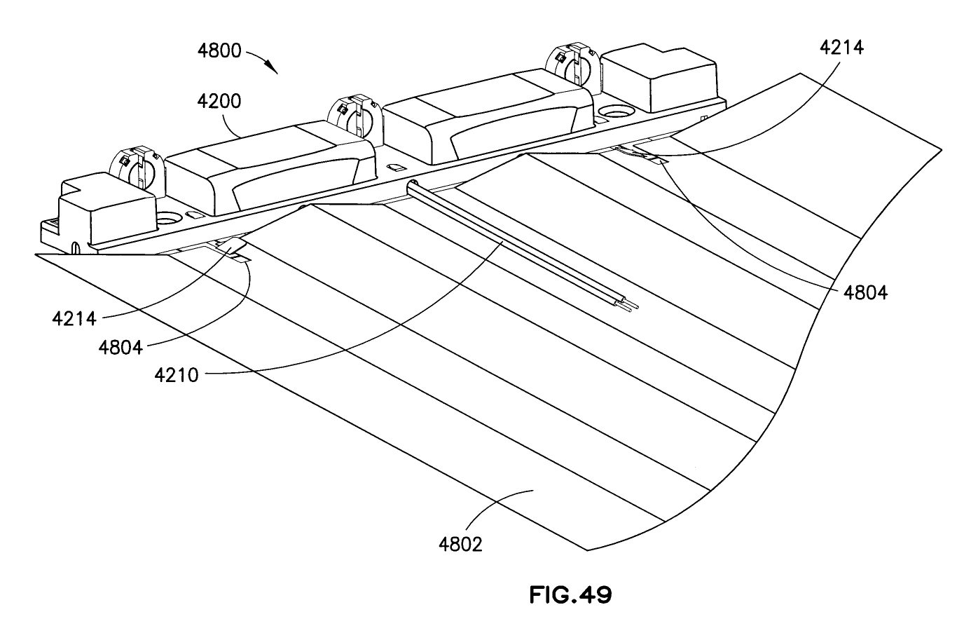

FIG. 48 shows a perspective view of a light fixture 4800 in accordance with another embodiment of the present disclosure. The light fixture 4800 comprises the first end section 4200 described with respect to FIG. 42 and the second end section 4300 described with respect to FIG. 43. The light fixture 4800 also includes a reflector 4802 positioned between the first end section 4200 and second end section 4300. The reflector 4802 is clipped onto and held in place by clips 4214 of the first end section 4200 and by clips 4306 of the second end section 4300. As shown, the conductors 4210 for providing power may be positioned on the side of the reflector 4802 where the lamps are held, but in some implementations may be positioned on the other side.

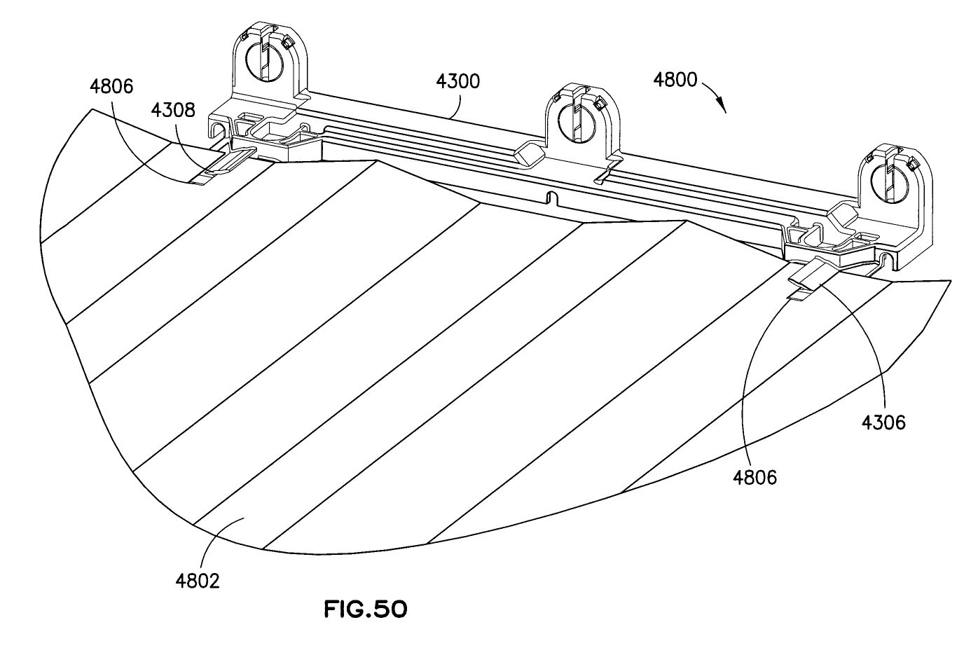

FIG. 49 shows a close-up, perspective view of the first end section 4200 of the light fixture 4800 shown in FIG. 48. FIG. 49 also shows the details of the clips 4214 of the first end section 4200 and slits 4804 in the end of the reflector 4802 that engage with the clips 4214. The reflector 4802 may be mounted to the first end section 4200 using clips 4214 without the need for additional tools or hardware.

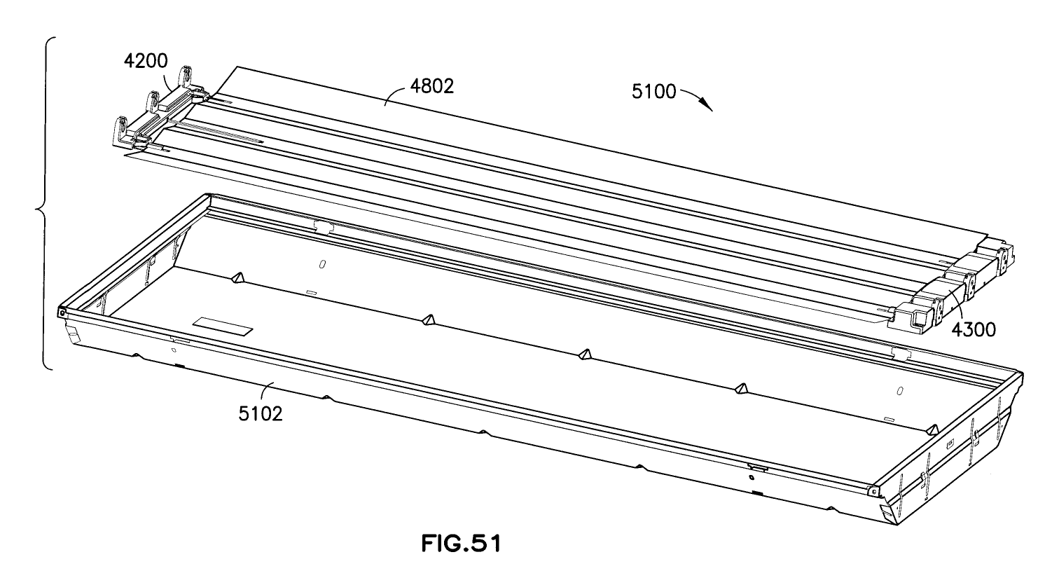

FIG. 50 shows a close-up, perspective view of the second end section 4300 of the light fixture 4800 shown in FIG. 48. FIG. 50 also shows the details of the clips 4306 of the second end section 4300 and slits 4806 in the end of the reflector 4802 that engage with the clips 4306. The reflector 4802 may be mounted to the second end section 4300 using clips 4306 without the need for additional tools or hardware.

FIG. 51 shows the modular components of a light fixture 5100 according to an implementation of the present disclosure. The light fixture 5100 in this embodiment includes the first end section 4200, the second end section 4300, the reflector 4802, and an enclosure 5102. The enclosure 5102 is configured to support the other components of the light fixture 5100.

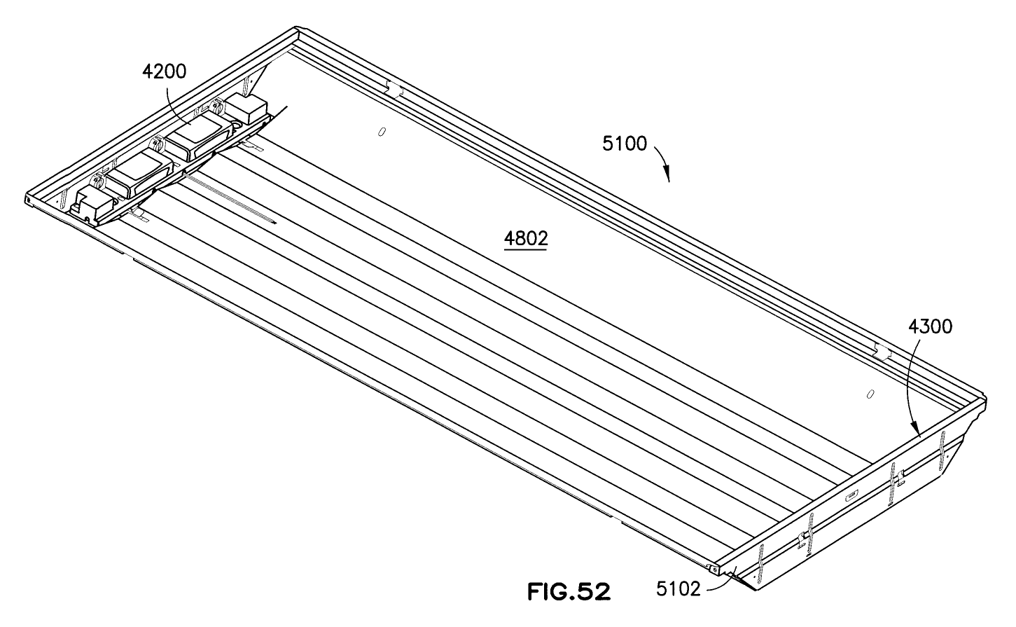

FIG. 52 shows a perspective view of the light fixture 5100 of FIG. 51 when the modular components are combined together to form a unitary structure. In some embodiments, the end sections 4200, 4300 may be installed in the light fixture 5100 first. Then, the reflector 4802 may be installed by connecting the slits in the reflector to the corresponding clips of the end sections. Alternatively, the reflector 4802 may be connected to the clips first, and then the entire assembly can be installed in the enclosure.

According to various implementations, a modular light fixture may comprise a first end section having a first housing and a first lamp holder, a second end section having a second lamp holder, and a ballast located in an interior of the first housing. The modular light fixture may also comprise at least one environmental sensor configured to sense at least one environmental condition and an electronic control circuit configured to receive a signal indicative of the at least one environmental condition sensed by the at least one environmental sensor. The first lamp holder may be configured to support a first end of a lamp and the second lamp holder may be configured to support a second end of the lamp.

In addition, the modular light fixture may further comprise at least one control conductor configured to communicate signals between the first end section and the second end section. The second end section may comprise a second housing, such that the electronic control circuit is located in an interior of the second housing. The electronic control circuit may be configured to communicate control signals to the ballast via the at least one control conductor.

The at least one environmental sensor may comprise at least one occupancy sensor configured to detect whether or not a room, which is at least partially illuminated by the lamp, is occupied by at least one person. When the room is not occupied for a predetermined length of time, the electronic control circuit may be configured to send a control signal along the at least one control conductor to cause the ballast to turn the lamp off or to dim the lamp.

In some embodiments, the at least one environmental sensor may comprise at least one photosensor configured to detect an amount of light in a room that is at least partially illuminated by the lamp. The electronic control circuit is configured to determine a portion of the detected amount of light that is independent of the effect of the illumination of the lamp. When the portion of the detected amount of light is above a predetermined level, the electronic control circuit may be configured to send a control signal along the at least one control conductor to cause the ballast to turn the lamp off or to cause the ballast to dim the lamp.

The first end section may comprise a third lamp holder and the second end section may comprise a fourth lamp holder. The third lamp holder is configured to support a first end of a second lamp and the fourth lamp holder is configured to support a second end of the second lamp. In some embodiments, the first end section comprises at least one fifth lamp holder and the second end section comprises at least one sixth lamp holder. The at least one fifth lamp holder is configured to support a first end of at least one third lamp and the at least one sixth lamp holder is configured to support a second end of the at least one third lamp.

The light fixture may comprise a wireless receiver coupled to the electronic control circuit. The wireless receiver is configured to receive wireless signals that include information regarding the illumination of the light fixture. The electronic control circuit is configured to individually illuminate the light fixture according to the received wireless signals. The wireless receiver is configured to receive automated demand response (ADR) signals from a power utility company, and the controller circuit is configured to individually illuminate the light fixture according to the ADR signals.

The modular light fixture may further comprise an addressing switch associated with the light fixture. The addressing switch is configured to provide an address to the electronic control circuit for individually identifying the light fixture. The addressing switch may be programmable or a hardware switch.

In some embodiments, the modular light fixture further comprises a reflector. The first end section may further comprise a first clip and a second clip and the second end section may further comprise a third clip and a fourth clip. The first clip, second clip, third clip, and fourth clip are configured to be removably attached to the reflector for supporting the reflector. The modular light fixture may further comprise an enclosure configured to support the first end section, second end section, and reflector to form a unitary structure.

The modular light fixture may further comprise at least one power conductor configured to provide power to the ballast and the electronic control circuit. The ballast may comprise a dimming ballast, wherein the dimming ballast provides stepwise dimming.

According to some embodiments, the modular light fixture may further comprise an emergency backup power supply contained within the first or second end. The emergency backup power supply module may comprise at least one rechargeable battery, a charging circuit configured to charge the at least one rechargeable battery, and a power outage detecting circuit configured to detect the occurrence of a power outage. When the power outage detecting circuit detects a power outage, the at least one rechargeable battery may be configured to provide power to the ballast and electronic control circuit. The charging circuit charges the at least one rechargeable battery from power that is also supplied to the ballast and electronic control circuit. The charging circuit may alternatively charge the at least one rechargeable battery from power supplied by a remote circuit. This embodiment may also include an accessible test switch integrated into the housing for testing the back-up power and at least one LED to show whether a back-up power test has passed or failed. A remote test switch may also be used for testing the back-up power.

The lamp supported by the modular light fixture may be a fluorescent lamp, a light emitting diode (LED) lamp, or other type of lamp.

Another modular light fixture is disclosed in which it comprises a first end section having a first housing and a first lamp holder, a second end section having a second lamp holder, a ballast located in an interior of the first housing, and at least one control conductor configured to communicate signals between the first end section and the second end section. The first lamp holder may be configured to support a first end of a lamp and the second lamp holder is configured to support a second end of the lamp.

Furthermore, the modular light fixture may comprise at least one environmental sensor configured to sense at least one environmental condition and an electronic control circuit configured to receive signals indicative of the at least one environmental condition. The second end section may comprise a second housing, and the electronic control circuit may be located in an interior of the second housing. The electronic control circuit may be configured to communicate control signals to the ballast via the at least one control conductor.

Another modular light fixture is disclosed herein, wherein the modular light fixture comprises a first end section having a first housing, a first lamp holder, a first clip, and a second clip, and a second end section having a second lamp holder, a third clip, and a fourth clip. The modular light fixture also comprises a ballast located in an interior of the first housing and a reflector that is attached to the first clip, second clip, third clip, and fourth clip. The first lamp holder is configured to support a first end of a lamp and the second lamp holder is configured to support a second end of the lamp.

In this embodiment, the reflector is removably attached to the first clip, second clip, third clip, and fourth clip. Also, the modular light fixture may further comprise an enclosure configured to support the first end section, second end section, and reflector to form a unitary structure. The modular light fixture may further comprise at least one environmental sensor located in a second housing of the second end section, wherein the at least one environmental sensor is configured to sense at least one environmental condition, and an electronic control circuit located in the second housing, wherein the electronic control circuit is configured to receive a signal indicative of the at least one environmental condition sensed by the at least one environmental sensor. The modular light fixture may further comprise at least one control conductor configured to communicate signals between the first end section and the second end section.

A method of assembling a modular light fixture is also disclosed in the present disclosure. The method comprises the step of providing a first end section having a first housing, a first lamp holder, a first clip, and a second clip and providing a second end section having a second lamp holder, a third clip, and a fourth clip. The method also includes installing a ballast in an interior of the first housing. Also, the method includes attaching a reflector to the first clip and the second clip of the first end section and attaching the reflector to the third clip and the fourth clip of the second end section. Finally, the method includes connecting a first end of a lamp to the first lamp holder of the first end section and connecting a second end of the lamp to the second lamp holder of the second end section.

The method may further comprise the step of installing the first end section, second end section, and reflector in an enclosure to form a unitary structure. The method may also comprise installing at least one environmental sensor in an interior and/or exterior of a second housing of the second end section, the at least one environmental sensor configured to sense at least one environmental condition, and installing an electronic control circuit in the interior of the second housing, the electronic control circuit configured to receive a signal indicative of the at least one environmental condition sensed by the at least one environmental sensor. The method may also include attaching at least one control conductor between the electronic control circuit and the ballast. In an alternative embodiment, the method may comprise installing the at least one environmental sensor in an interior and/or exterior of the first end section.

The method may also comprise installing at least one receiver in an interior and/or exterior of the first or second housing, the receiver being configured to receive (e.g., via an antenna) wireless control signals. The method may include wirelessly receiving the control signals and forwarding the control signals to the ballast and/or the electronic control circuit to control at least one lamp disposed in the light fixture. The wireless receiver may be configured to receive automated demand response (ADR) signals from a power utility company, and wherein the electronic control circuit is configured to control the lamp according to the ADR signals.

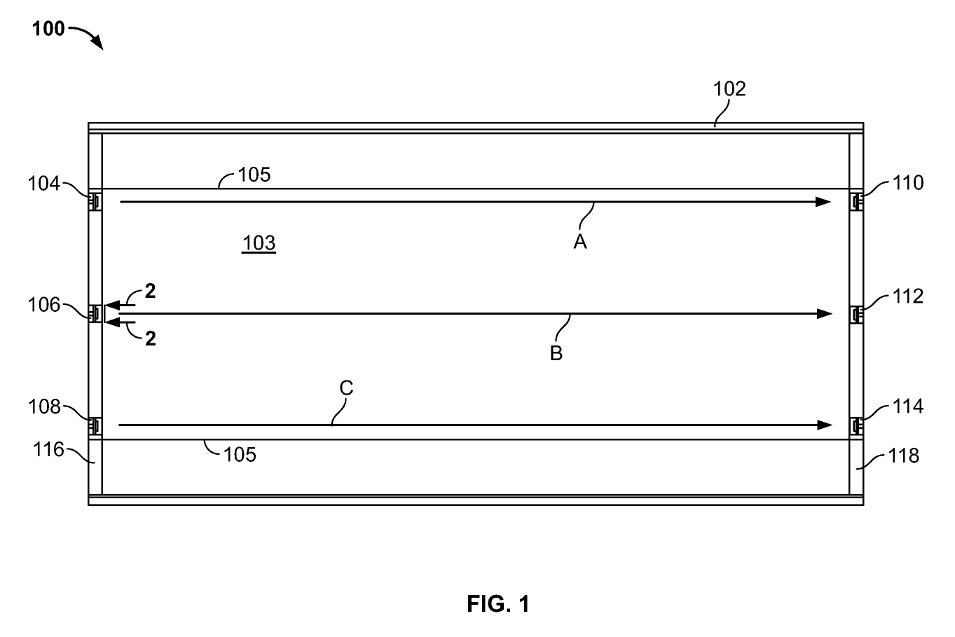

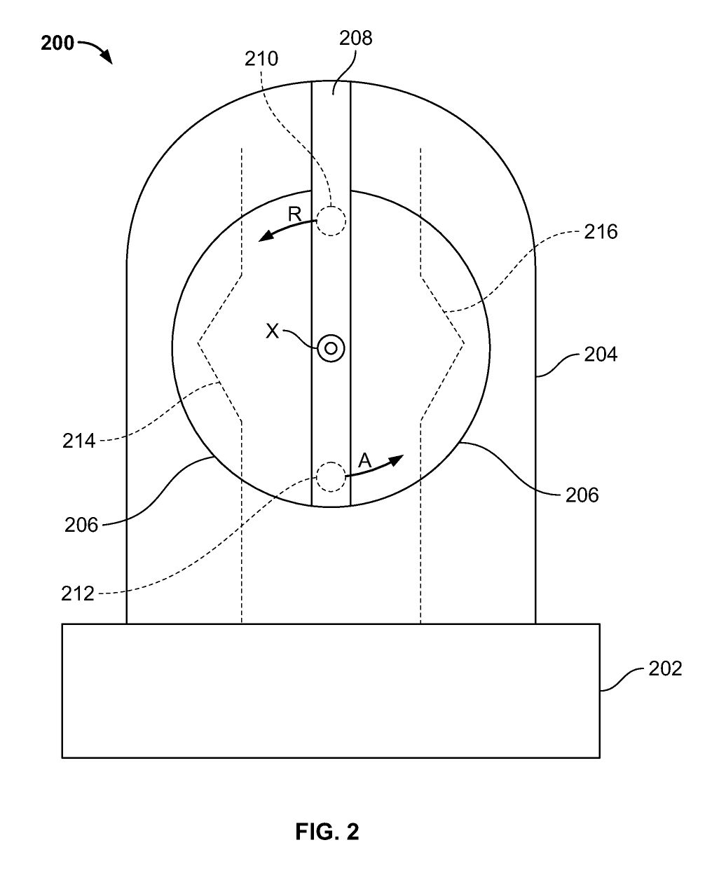

It will be appreciated that features of apparatus shown and described in connection with only one or more of FIGS. 1-52 may be combined with features shown and described in connection with any one or more of the other FIGS. For example, apparatus and methods for supporting a lamp holder may be combined in any suitable manner with apparatus and methods for connecting a lamp holder to a ballast.

Thus, apparatus and methods for supporting and energizing a lamp have been provided. Persons skilled in the art will appreciate that the present invention can be practiced by other than the described embodiments, which are presented for purposes of illustration rather than of limitation, and the present invention is limited only by the claims which follow.

What is claimed is:

1. A modular light fixture comprising:
a first end section having a first housing and a first lamp holder;
a second end section having a second housing and a second lamp holder, the first lamp holder being configured to support a first end of a lamp and the second lamp holder being configured to support a second end of the lamp;
a ballast located in an interior of the first housing;
at least one environmental sensor configured to sense at least one environmental condition;
an electronic control circuit located in an interior of the second housing configured to receive a signal indicative of the at least one environmental condition sensed by the at least one environmental sensor; and
at least one control conductor configured to communicate signals between the first end section and the second end section,
wherein the electronic control circuit is configured to communicate control signals to the ballast via the at least one control conductor.

2. The modular light fixture of claim 1, wherein the at least one environmental sensor is located remotely from one of the first housing or second housing.

3. The modular light fixture of claim 1, wherein the at least one environmental sensor is located in and protruding from the second housing.

4. The modular light fixture of claim 1, wherein the at least one environmental sensor comprises an occupancy sensor configured to detect whether or not a space is occupied by at least one person.

5. The modular light fixture of claim 4, wherein, when the occupancy sensor detects occupancy, the electronic control circuit is configured to send a control signal along the at least one control conductor to instruct the ballast to turn the lamp on.

6. The modular light fixture of claim 4, wherein, when the space is not occupied for a predetermined length of time, the electronic control circuit is configured to send a control signal along the at least one control conductor to instruct the ballast to turn the lamp off.

7. The modular light fixture of claim 4, wherein, when the space is not occupied for a predetermined length of time, the electronic control circuit is configured to send a control signal along the at least one control conductor to instruct the ballast to dim the lamp.

8. The modular light fixture of claim 1, wherein the at least one environmental sensor comprises an ambient light detector configured to detect an amount of light in a space.

9. The modular light fixture of claim 8, wherein, when the ambient light detector detects an amount of light above a predetermined level, the electronic control circuit is configured to send a control signal along the at least one control conductor to cause the ballast to turn the lamp off.

10. The modular light fixture of claim 8, wherein, when the ambient light detector detects an amount of light above a predetermined level, the electronic control circuit is configured to send a control signal along the at least one control conductor to cause the ballast to dim the lamp.

11. The modular light fixture of claim 1, wherein the first end section comprises at least one third lamp holder and the second end section comprises at least one fourth lamp holder, and wherein the at least one third lamp holder is configured to support a first end of at least one second lamp and the at least one fourth lamp holder is configured to support a second end of the at least one second lamp.

12. The modular light fixture of claim 1, further comprising a wireless receiver located in and protruding from one of the first and second housings, the wireless receiver being coupled to the electronic control circuit, wherein the wireless receiver is configured to receive wireless signals that include information regarding illumination of the lamp, and wherein the electronic control circuit is configured to individually illuminate the lamp according to the received wireless signals.

13. The modular light fixture of claim 12, wherein the wireless receiver is configured to receive automated demand response (ADR) signals from a power utility company, and wherein the electronic control circuit is configured to control the lamp according to the ADR signals.

14. The modular light fixture of claim 12, further comprising an addressing switch associated with the electronic control circuit, wherein the addressing switch is configured to provide a first address to the controller circuit for identifying the lamp.

15. The modular light fixture of claim 14, wherein the addressing switch is programmable.

16. The modular light fixture of claim 14, wherein the addressing switch is a hardware switch.

17. The modular light fixture of claim 1, further comprising a reflector.

18. The modular light fixture of claim 17, wherein the first end section further comprises a first clip and a second clip and the second end section further comprises a third clip and a fourth clip, and wherein the first clip, second clip, third clip, and fourth clip are configured to be removably attached to the reflector for supporting the reflector.

19. The modular light fixture of claim 18, further comprising an enclosure configured to support the first end section, second end section, and reflector to form a unitary structure.

20. The modular light fixture of claim 1, further comprising at least one power conductor configured to provide power to the ballast and the electronic control circuit.

21. The modular light fixture of claim 1, wherein the ballast comprises a dimming ballast.

22. The modular light fixture of claim 21, wherein the dimming ballast provides stepwise dimming.

23. The modular light fixture of claim 1, further comprising an emergency backup power supply contained within one of the first housing or the second housing.

24. The modular light fixture of claim 23, wherein the emergency backup power supply comprises at least one rechargeable battery, a charging circuit configured to charge the at least one rechargeable battery, and a power outage detecting circuit configured to detect the occurrence of a power outage.

25. The modular light fixture of claim 24, wherein, when the power outage detecting circuit detects a power outage, the at least one rechargeable battery is configured to provide power to the ballast and electronic control circuit.

26. The modular light fixture of claim 24, wherein the charging circuit charges the at least one rechargeable battery from power that is also supplied to the ballast and electronic control circuit.

27. The modular light fixture of claim 24, wherein the charging circuit charges the at least one rechargeable battery from power supplied by a remote circuit.

28. The modular light fixture of claim 1, wherein the lamp is a fluorescent lamp.

29. The modular light fixture of claim 1, wherein the lamp is a light emitting diode (LED) lamp.

30. A modular light fixture comprising:
a first end section having a first housing and a first lamp holder;
a second end section having a second housing and a second lamp holder, the first lamp holder being configured to support a first end of a lamp and the second lamp holder being configured to support a second end of the lamp;
the first end section being electrically coupled to the second end section;
a ballast located in an interior of the first housing; and
an emergency backup power supply contained within one of the first housing or the second housing.

31. The modular light fixture of claim 30, wherein the emergency backup power supply comprises at least one rechargeable battery, a charging circuit configured to charge the at least one rechargeable battery, and a power outage detecting circuit configured to detect the occurrence of a power outage.

32. The modular light fixture of claim 31, wherein, when the power outage detecting circuit detects a power outage, the at least one rechargeable battery is configured to provide power to the ballast.

33. The modular light fixture of claim 31, wherein the charging circuit charges the at least one rechargeable battery from power that is also supplied to the ballast.

34. The modular light fixture of claim 31, wherein the charging circuit charges the at least one rechargeable battery from power supplied by a remote circuit.

35. The modular light fixture of claim 30, further comprising:
at least one environmental sensor configured to sense at least one environmental condition; and
an electronic control circuit configured to receive signals indicative of the at least one environmental condition.

36. The modular light fixture of claim 35, wherein the electronic control circuit is located in an interior of the second housing, and wherein the electronic control circuit is configured to communicate the control signals to the ballast via at least one control conductor configured to communicate control signals between the first end section and the second end section.

37. A method of assembling a modular light fixture comprising:
providing a first end section having a first housing and a first lamp holder;
providing a second end section having a second housing and a second lamp holder;
installing a ballast in an interior of the first housing;
installing an electronic control circuit in an interior of the second housing;
mounting the first end section in a first end of a light fixture enclosure and the second end section in a second end of the light fixture enclosure;
attaching at least one control conductor between the electronic control circuit and the ballast; and
installing at least one environmental sensor in the interior of the second housing of the second end section, the at least one environmental sensor configured to sense at least one environmental condition,
wherein the electronic control circuit is configured to receive a signal indicative of the at least one environmental condition sensed by the at least one environmental sensor and to communicate control signals to the ballast via the at least one control conductor.

38. The method of claim 37, further comprising:
providing at least one first clip on the first end section;
providing at least one second clip on the second end section;
attaching a reflector to the at least one first clip and the at least one second clip;
connecting a first end of a lamp to the first lamp holder of the first end section; and
connecting a second end of the lamp to the second lamp holder of the second end section.
